(19) United States
(12) Patent Application Publication
(10) Pub. No.: US 2026/0065163 A1
(43) Pub. Date: Mar. 5, 2026

(54) ADAPTIVE ARTIFICIAL INTELLIGENCE/MACHINE LEARNING

(71) Applicant: TDK U.S.A Corporation, Uniondale, NY (US)

(72) Inventor: Mamdouh Yanni, Brentwood, CA (US)

(21) Appl. No.: 19/314,969

(22) Filed: Aug. 29, 2025

Related U.S. Application Data
(60) Provisional application No. 63/691,168, filed on Sep. 5, 2024.

(51) Int. Cl. G06N 20/00; H03K 5/1252

(52) U.S. Cl. CPC G06N 20/00; H03K 5/1252

(57) ABSTRACT

Enhanced adaptive noise cancellation of sensor signals to generate denoised sensor signals, which can be provided to an AI-based model to facilitate adaptive training and operation of the model, is presented. An adaptive noise canceler can adaptively filter a sensor signal, comprising sensor data and noise, received from a sensor(s) to cancel the noise from the sensor signal, based on an adaptive filter function and external reference signal received from a reference sensor(s), which can sense conditions associated with the sensor(s), or internal reference signal, to generate a denoised sensor signal that can comprise the sensor data. The adaptive noise canceler can comprise an interface component that can be configured to interface with the model and initiate training of the model by communication of the denoised sensor signal to an input port of the model, wherein the model can be trained based on the denoised sensor signal.

### CROSS-REFERENCE TO RELATED APPLICATION

This patent application claims priority to U.S. Provisional Patent Application No. 63/691,168, filed Sep. 5, 2024, and entitled, “ADAPTIVE ARTIFICIAL INTELLIGENCE/MACHINE LEARNING,” the entirety of which application is hereby incorporated by reference herein.

### BACKGROUND

Artificial intelligence (AI) or machine learning (ML) models can be trained to perform various desired tasks and can be used for various types of applications, such as, for example, natural language processing (NLP), image analysis, generic pattern identification, and/or other desired applications. In some instances, it can be desirable for an AI or ML model to be trained using sensor information (e.g., sensor measurements or other sensor information) obtained from sensors.

The above-described description is merely intended to provide a contextual overview relating to AI-based and sensor technologies, and is not intended to be exhaustive.

### SUMMARY

The following presents a simplified summary of various aspects of the disclosed subject matter in order to provide a basic understanding of some aspects described herein. This summary is not an extensive overview of the disclosed subject matter. It is intended to neither identify key or critical elements of the disclosed subject matter nor delineate the scope of such aspects. Its sole purpose is to present some concepts of the disclosed subject matter in a simplified form as a prelude to the more detailed description that is presented later.

In some embodiments, the disclosed subject matter can comprise a system that can comprise at least one memory that can store machine-executable components. The system also can comprise at least one processor that can execute the machine-executable components that can be stored in the at least one memory. The machine-executable components can comprise an adaptive noise canceler component that can be configured to adaptively filter a sensor signal, comprising sensor data, that can be received from a sensor component to cancel noise from the sensor signal, based at least in part on an adaptive filter function and an internal reference signal, to generate a denoised signal that can comprise the sensor data. The machine-executable components also can comprise an interface component that can be configured to interface with an artificial intelligence (AI)-based model and initiate training of the AI-based model by communication or application of the denoised signal to an input port of the AI-based model, wherein the AI-based model can be trained based at least in part on the denoised signal.

In certain embodiments, the disclosed subject matter can comprise a device that can comprise an adaptive noise canceler component that can be configured to adaptively filter a sensor signal, comprising sensor information, that can be received from a sensor component to filter out noise from the sensor signal, based at least in part on an adaptive filter function and a reference signal, to generate a noise-canceled signal that can comprise the sensor information and does not include the noise filtered out from the sensor signal. The device also can comprise an interface component that can be configured to interface with an AI-based model and facilitate training of the AI-based model by communication or application of the noise-canceled signal to an input port of the AI-based model, wherein the AI-based model can be trained based at least in part on the noise-canceled signal.

In some embodiments, the disclosed subject matter can comprise a method that can comprise: with regard to a sensor signal received from a sensor, adaptively filtering the sensor signal, comprising sensor data and noise or interference information, to remove the noise or interference information from the sensor signal, based at least in part on an adaptive filter function and a reference signal, to generate a denoised signal that can comprise the sensor data and does not include the noise or interference information. The method also can comprise supplying the denoised signal to an output interface that is able to interface with an input port of or associated with an AI-based model to enable inputting of the denoised signal into, and training of, the AI-based model, wherein the AI-based model can be trained based at least in part on the denoised signal.

The following description and the annexed drawings set forth in detail certain illustrative aspects of the disclosed subject matter. These aspects are indicative, however, of but a few of the various ways in which the principles of the disclosed subject matter may be employed, and the disclosed subject matter is intended to include all such aspects and their equivalents. Other advantages and distinctive features of the disclosed subject matter will become apparent from the following detailed description of the disclosed subject matter when considered in conjunction with the drawings.

### BRIEF DESCRIPTION OF THE DRAWINGS

FIG. 1 illustrates illustrated is a block diagram of a non-limiting example system that can comprise an adaptive noise canceler component that can desirably and adaptively cancel noise in a sensor signal received from a sensor component to generate a denoised sensor signal that can be provided to an artificial intelligence (AI)-based model to facilitate training and operation (e.g., adaptive training and operation) of the AI-based model, in accordance with various aspects and embodiments of the disclosed subject matter.

FIG. 2 depicts a diagram of a non-limiting example graph that can present certain features, including hyperplanes and associated margins, relating to support vector machine (SVM) classifiers to facilitate illustrating how SVM classifiers (e.g., SVM classifier models) can operate to classify data and/or perform other SVM classification or machine learning tasks, in accordance with various aspects and embodiments of the disclosed subject matter.

FIG. 3 illustrates a diagram of a non-limiting example system that can comprise an adaptive noise canceler component that can employ a least mean squares (LMS) function and/or algorithm to facilitate desirably and adaptively canceling noise in a sensor signal received from a sensor component to generate a denoised sensor signal that can be provided to an AI-based model to facilitate training and operation (e.g., adaptive training and operation) of the AI-based model, in accordance with various aspects and embodiments of the disclosed subject matter.

FIG. 4 depicts a block diagram of a non-limiting example system that can comprise an adaptive noise canceler component that can desirably and adaptively cancel noise in a sensor signal received from a sensor component, based at least in part on an external reference signal and an adaptive filter function, to generate a denoised sensor signal that can be provided to an AI-based model to facilitate training and operation (e.g., adaptive training and operation) of the AI-based model, in accordance with various aspects and embodiments of the disclosed subject matter.

FIG. 5 depicts a block diagram of a non-limiting example AI component that can receive sensor signals (e.g., denoised sensor signals) from the adaptive noise canceler component and can employ an AI-based model(s) to perform an AI-based analysis on data, including the sensor signals, to facilitate training of the AI-based model(s) and generating AI-based analysis results, in accordance with various aspects and embodiments of the disclosed subject matter.

FIG. 6 illustrates a flow diagram of an example method that that can desirably and adaptively cancel noise in a sensor signal received from a sensor component to generate a denoised sensor signal that can be provided to an AI-based model to facilitate training (e.g., adaptive training) of the AI-based model, in accordance with various aspects and embodiments of the disclosed subject matter.

FIGS. 7 and 8 illustrate a flow diagram of another non-limiting example method that that can desirably and adaptively cancel noise in a sensor signal received from a sensor component to generate a denoised sensor signal that can be provided to an AI-based model to facilitate training (e.g., adaptive training) of the AI-based model, in accordance with various aspects and embodiments of the disclosed subject matter.

FIG. 9 illustrates a non-limiting example block diagram of an example computing environment in which the various embodiments of the embodiments described herein can be implemented.

### DETAILED DESCRIPTION

The disclosed subject matter is described with reference to the drawings, wherein like reference numerals are used to refer to like elements throughout. In the following description, for purposes of explanation, numerous specific details are set forth in order to provide a thorough understanding of the various embodiments of the subject disclosure. It may be evident, however, that the disclosed subject matter may be practiced without these specific details. In other instances, well-known structures and devices are shown in block diagram form in order to facilitate describing the various embodiments herein.

Artificial intelligence (AI), including machine learning (ML), can be utilized for a variety of purposes and can process a variety of information. AI-based models (e.g., AI model, ML model, neural network model, graph mining model, support vector machine (SVM) classifier model, decision tree model, or other type of AI-based model) can be trained based at least in part on data, which can be or can include training data, that can be input to and processed by the AI-based models. In some cases, sensor data obtained from a sensor can be input to an AI-based system, comprising an AI-based model (also referred to herein as a model), to facilitate training of the model and/or utilization of the model to process the sensor data (e.g., AI-based analysis and processing of the sensor data).

However, certain sensors (e.g., accelerometers, gyroscopes, gas sensors, and/or certain other sensors) can have undesirable biases and/or drift behaviors that can change over time and can impact (e.g., negatively impact) the stability or accuracy of their measurements (e.g., measurements or sensing of conditions associated with the sensors). Due to such undesirable biases and/or drift behaviors, utilizing these sensors, for example, to provide sensor data to an AI-based system to facilitate training a model can effectively result in the AI-based system, including the model, dealing with “moving goal posts,” as the undesirable biases and/or drift behaviors of the sensors may change or vary, and can result in unreliable or inaccurate sensor data with regard to measured or sensed conditions by the sensors. The undesirable biases and/or drift behaviors of signals received from sensors can result in undesirable (e.g., inaccurate, unacceptable, unsuitable, inefficient, or suboptimal) training of a model when such sensor signals are input to the model as part of training of the model, and can result in the undesirably trained model producing undesirable (e.g., inaccurate, unacceptable, unsuitable, inefficient, or suboptimal) output data. Thus, existing systems and techniques that utilize sensor signals (e.g., comprising sensor data or measurements) of sensors, which can be experiencing bias and/or drift behaviors, as input data for training of AI-based models or functions can be deficient in a variety of ways, including resulting in undesirable model training and undesirable output results produced by the undesirably trained model.

When utilizing sensors that can have biases and/or drift, whether the bias or drift is of a stochastic nature or a deterministic nature, it can be desirable (e.g., wanted, needed, suitable, or optimal) to address and/or mitigate such biases and/or drift of such sensors to produce reliable, accurate, and/or stable sensor data (e.g., measurements from sensors) that can be utilized in an AI-based environment (e.g., can be utilized to train AI-based models).

To overcome the various issues and deficiencies of existing systems, methods, and techniques, the disclosed subject matter can employ techniques, systems, devices, and methods that can desirably (e.g., suitably, efficiently, enhancedly, and/or optimally) and adaptively cancel noise (e.g., noise caused by sensor bias and/or drift behaviors, and/or environmental, interference, and/or other behaviors or conditions) in signals generated by sensors to produce a denoised sensor signal that can be input to an AI-based model to facilitate desirable training and operation (e.g., adaptive training and operation) of the AI-based model, in accordance with various aspects and embodiments of the disclosed subject matter. A system or device can comprise an adaptive noise canceler component that, at its input (e.g., input port), can be associated with (e.g., communicatively and/or electronically connected to) an output (e.g., output port) of a sensor component. The output of the adaptive noise canceler component can be associated with (e.g., communicatively and/or electronically connected to) an input of an AI component, which can comprise an AI-based model and/or AI-based function (e.g., the output of the adaptive noise canceler component can be connected to an input of the AI-based model).

The adaptive noise canceler component can deploy adaptive noise cancellation (e.g., adaptive echo-cancellation) techniques to deal with and mitigate (e.g., reduce, minimize, or eliminate) sensor bias and/or drift behaviors of the sensor component, and/or the effects or errors associated with environmental, interference, and/or other behaviors or conditions of or associated with the sensor component. The adaptive noise canceler component can cancel or filter out (e.g., can be configured to adaptively cancel or filter out) noise from (e.g., can denoise) sensor signals, comprising sensor data (e.g., sensor measurements or other sensor data), received from the sensor component, and can communicate the denoised sensor signal to the input of the AI-based model to facilitate (e.g., to initiate, enable, or otherwise facilitate) training of the AI-based model based at least in part on the denoised sensor signal (e.g., the denoised sensor data in the denoised sensor signal). The adaptive noise canceler component can estimate or determine (e.g., can automatically, dynamically, quickly, efficiently, enhancedly, and/or optimally estimate or determine, in real time or “on the fly”) noise error (e.g., bias, drift, environmental-related, interference-related, and/or other errors) in the signal (e.g., noisy signal) received from the sensor component, can adaptively remove (e.g., filter out) or subtract the estimated or determined noise error from the noisy signal to generate a denoised (e.g., a clean or virtually clean) output signal (e.g., a signal that can be void or virtually void of bias, drift, environmental-related, interference-related, and/or other errors), and can communicate the denoised output signal, comprising the sensor data (e.g., denoised sensor data), to the input of the AI-based model to facilitate training of the AI-based model.

In some embodiments, the adaptive noise canceler component can perform such desirable adaptive noise cancellation on the sensor signals without having to utilize (e.g., without requiring) any external reference signals. For instance, the adaptive noise canceler component can perform such desirable adaptive noise cancellation on the sensor signals by utilizing an internal reference signal (e.g., an internal reference signal of the adaptive noise canceler component) that can be set to a defined constant value (e.g., a defined constant value of one (e.g., a binary, logic, or digital value of one)). In certain embodiments, the adaptive noise canceler component can be configured in a bias/drift setup, and can utilize a desirably low (e.g., a minimal) amount of processing (e.g., central processing unit (CPU), controller, microprocessor, or microcontroller) and memory resources.

The adaptive noise canceler component, by de-noising the sensor signals utilized for training of the AI-based system (e.g., AI-based model of the AI-based system), can thereby desirably render or make the AI-based system adaptive (e.g., and adaptive AI or ML system) as a whole, since the adaptive noise canceler component can mitigate (e.g., remove or filter out, or at least substantially remove or filter out) and/or stabilize the noise disturbances in the sensor signals (and associated sensor data) prior to the training, cross validation, and test operations performed on the AI-based model or function of the AI-based system. This can lead to desirably stabilized deployment of the system (e.g., the sensor component, adaptive noise canceler component, and the AI-based system) in the field with no or at least virtually no additional hardware infrastructure having to be utilized, and with low (e.g., minimal) processing and memory loading.

These and other aspects of the disclosed subject matter are described with regard to the figures.

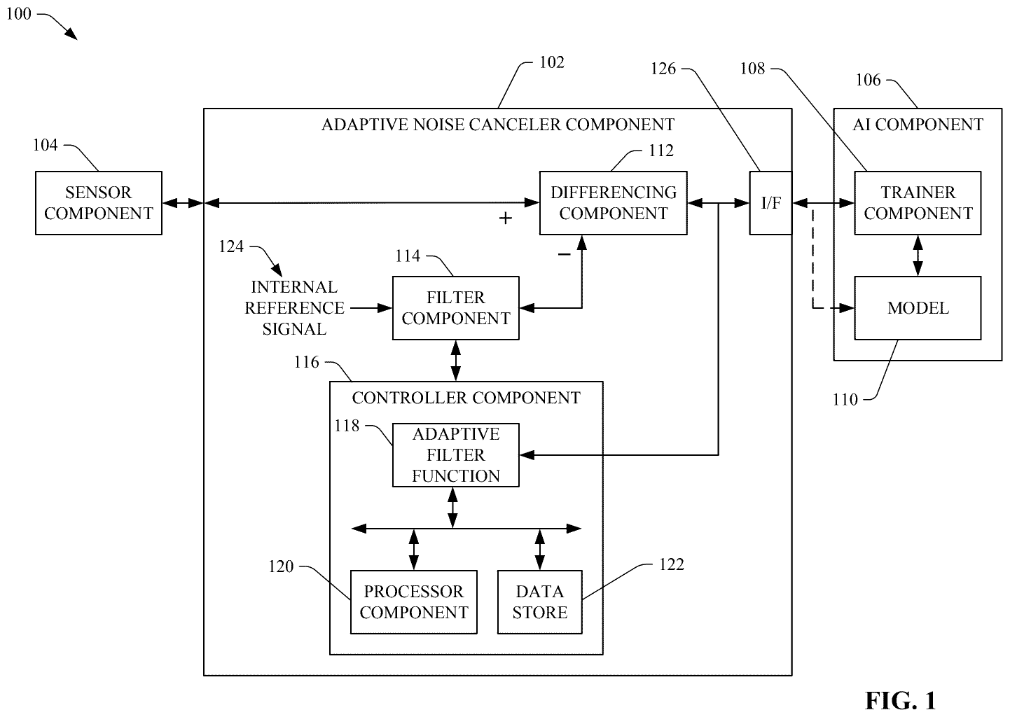

Turning to FIG. 1, illustrated is a block diagram of a non-limiting example system 100 that can comprise an adaptive noise canceler component that can desirably and adaptively cancel noise in a sensor signal received from a sensor component to generate a denoised sensor signal that can be provided to an AI-based model to facilitate training and operation (e.g., adaptive training and operation) of the AI-based model, in accordance with various aspects and embodiments of the disclosed subject matter. The system 100 can comprise an adaptive noise canceler component 102 that can have an input (e.g., input port) that can be associated with (e.g., communicatively and/or electronically connected to) a sensor component 104 (e.g., an output port of the sensor component 104). The sensor component 104 can be or can comprise one or more sensors, such as, for example, an accelerometer, a gyroscope, a magnetometer, an environmental condition sensor, a gas sensor, a pressure sensor (e.g., an air pressure sensor, a touch pressure sensor, or other type of pressure sensor), a temperature sensor, an optical sensor, an image sensor, a chemical sensor, a sound sensor, a quartz sensor, a health sensor, a photoplethysmography sensor, an electrocardiogramsor, and/or another type of sensor. The sensor(s) of the sensor component 104 can be any type of sensor that can experience and/or can be susceptible to noise or interference, such as, for example, bias and/or drift behaviors, and/or environmental, interference, and/or other behaviors or conditions, in or associated with the sensor or signals generated by the sensor(s). In some embodiments, the sensor component 104 can be a microelectromechanical systems (MEMS) or semiconductor sensor component that can comprise one or more MEMS or semiconductor sensors that can be formed using MEMS technology. In certain embodiments, the adaptive noise canceler component 102, or certain components thereof, can be formed using MEMS technology.

In some embodiments, an output (e.g., output port) of the adaptive noise canceler component 102 can be associated with (e.g., communicatively and/or electronically connected to and/or interfaced with) an input of an AI component 106. In certain embodiments, the AI component 106 can comprise a trainer component 108 and one or more AI-based models, such as AI-based model 110 (the AI-based models also can be referred to herein as models). The model 110 can be, for example, an AI model, ML model, neural network model, transformer-based model, generative pre-trained transformer (GPT)-type model, graph mining model, SVM classifier model, other type of classifier model, decision tree model, or other type of AI-based model. The model 110 can be trained to perform AI-based analysis on data to generate data results based at least in part on the AI-based analysis. For instance, the model 110 (e.g., trained model) can receive input data. The model 110 (and/or an AI-based function of the AI component 106) can perform an AI-based analysis on the input data (e.g., denoised sensor data) and/or other data, and can generate data results as an output from the model 110 based at least in part on the results of the AI-based analysis. The data results can comprise, for example, prediction data, probability data, determination or decision data, and/or other data that can be determined and/or generated by the model 110 based at least in part on the input data input to the model 110, the training of the model 110, and the AI-based analysis performed on the input data and/or other data by the model 110 (and/or the AI-based function).

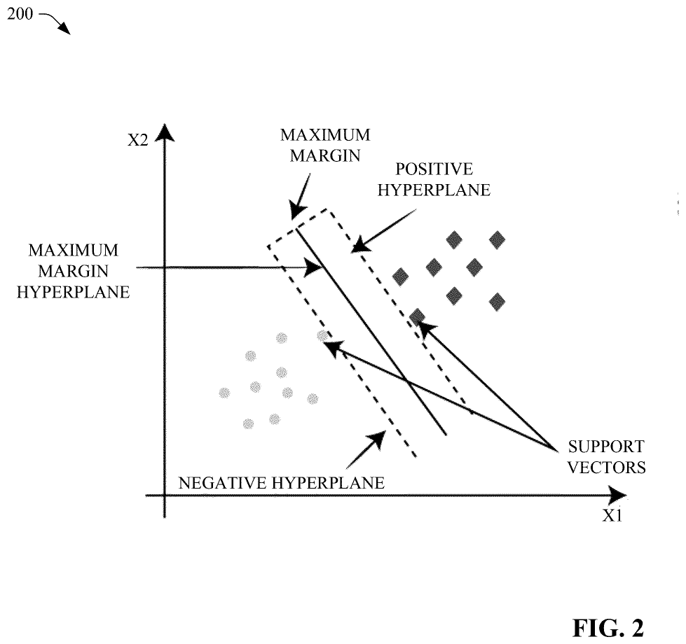

Referring briefly to FIG. 2 (along with FIG. 1), FIG. 2 depicts a diagram of a non-limiting example graph 200 that can present certain features, including hyperplanes and associated margins, relating to SVM classifiers to facilitate illustrating how SVM classifiers (e.g., SVM classifier models) can operate to classify data and/or perform other SVM classification or machine learning tasks, in accordance with various aspects and embodiments of the disclosed subject matter. SVMs, which also can be known or referred to as maximal margin classifiers, utilized as a regression or as a classifier, can be a desirable (e.g., fundamental or pivotal) algorithm in the field of machine learning. SVMs are recognize for their accuracy and computational efficiency. SVMs are a type of supervised machine learning algorithm and usually can be deployed for classification or quantification tasks. Applications for SVMs can span across all or various aspects of machine learning systems, including, for example, natural language processing (NLP), image analysis, generic pattern identification, and/or other desired applications. A primary directive of an SVM can be to identify a hyperplane in a multi-dimensional space (where the number of dimensions can be dictated by the number of features) that effectively can separate the data points. The hyperplane shape can change dependent on the number of features. For a 2-features dataset, the hyperplane can be a one-dimensional (1-D) line; for a 3-feature dataset, the hyperplane can be a two-dimensional (2-D) plane; and this can become progressively more complex as the number of features in a dataset increases.

There can be multiple potential hyperplanes that can be chosen to divide the data into two groups. The aim can be to select the hyperplane that can maximize the separation, resulting in the widest gap between the data points of each class, thus achieving maximal margin between classes under consideration. This increased gap can enhance the reliability of the classification by the SVM and can enable more confident predictions for future data points. Hyperplanes can serve as decision boundaries for data classification by the SVM. Data points on one side of the hyperplane can be assigned to one class (e.g., by the SVM), while other data points on the other side can belong to, and can be assigned to, the other class (e.g., by the SVM). The shape of the hyperplane can vary, for example, depending on the number of features. Support vectors can be data points that are near the hyperplane and have a significant influence on determining its position and orientation. By selecting these support vectors, the margin of the classifier can be optimized. Removing these support vectors would cause a shift in the position of the hyperplane. Therefore, these points can be of significant use or value (e.g., can be fundamental, important, or crucial) for constructing an effective SVM model.

It is to be appreciated and understood that, while some embodiments are described herein with regard to an SVM model, in accordance with various other embodiments, virtually any desired type of model (e.g., AI-based model) can be utilized by the AI component 106 and trained based at least in part on training data, comprising denoised sensor data, such as described herein.

With further regard to the system 100, for a variety of applications, it can be desirable to train an AI-based model based at least in part on sensor signals, comprising sensor data, that can be input to the AI-based model to train the model. However, as disclosed, existing systems and techniques for training AI-based models using sensor signals can be deficient in a number of ways, including that certain sensors and sensor signals can experience noise or interference (e.g., bias, drift, environmental-related, interference-related, and/or other behaviors), which can negatively impact (e.g., render inaccurate) the sensor data (e.g., sensor measurements or other sensor data) in the sensor signals, and which can thereby result in undesirable (e.g., inaccurate, unacceptable, unsuitable, inefficient, or suboptimal) training of the AI-based models, and undesirable (e.g., inaccurate, unacceptable, unsuitable, inefficient, or suboptimal) performance of and output data (e.g., data results) generated by the AI-based models. For instance, from the disclosed description of SVM classifier models, it can readily be seen how undesirable noise in sensor signals can negatively impact the training of SVM classifier models and the performance of (undesirably) trained SVM classifier models.

The disclosed subject matter (e.g., the system 100, and the techniques and methods, described herein) can overcome the various issues and deficiencies of existing systems, methods, and techniques with regard to providing data to AI-based models and training AI-based models using such data. In that regard, the system 100 can employ the adaptive noise canceler component 102 that can be configured to desirably (e.g., automatically, dynamically, suitably, quickly, efficiently, enhancedly, and/or optimally) process a sensor signal that can be received from the sensor component 104 and adaptively cancel noise (e.g., bias and/or drift related noise and/or other noise) that can be in the sensor signal to generate a denoised or filtered sensor signal that can comprise the sensor data of the sensor signal, but can have the noise portion (or at least a desirably substantial amount of the noise) of the sensor signal canceled (e.g., removed or filtered out). The adaptive noise canceler component 102 can communicate (e.g., in real time or near real time) the denoised sensor signal, via the output port (e.g., interface component) of the adaptive noise canceler component 102, to the input of the AI component 106 and/or the input of the model 110 to facilitate training of the model 110.

The model 110 can be desirably trained (e.g., by the trainer component 108) based at least in part on the denoised sensor signal(s), comprising the sensor data, received from the adaptive noise canceler component 102. As a result of the adaptive noise canceler component 102 canceling the noise in the sensor signals received from the sensor component 104 and providing denoised sensor signals, comprising the sensor data, to the model 110 for training of the model 110, the training of the model 110 can be enhanced (e.g., improved) and can be performed more accurately and efficiently, and the data results produced by the trained model 110 can be enhanced (e.g., can be improved, more accurate, and/or more efficiently obtained), as compared to existing systems and techniques for training models and using trained models.

With further regard to the features and functions of the adaptive noise canceler component 102, in some embodiments, the adaptive noise canceler component 102 can comprise a differencing component 112, a filter component 114 (e.g., an adaptive or adjustable filter), and a controller component 116 (also referred to herein as an adaptive noise canceler controller component). In certain embodiments, the controller component 116 can comprise an adaptive filter function 118 that can be utilized to facilitate estimating or determining noise in a sensor signal received from the sensor component 104 and canceling the noise from the sensor signal to generate a denoised sensor signal, such as described herein. In some embodiments, the controller component 116 can comprise or can be associated with (e.g., communicatively and/or electronically connected to) a processor component 120 and/or a data store 122 that can be associated with the processor component 120. The data store 122 can comprise various types of information, including information relating to the adaptive filter function 118, processing of sensor signals, canceling noise from sensor signals, instructions, control-related information, and/or other desired information. The processor component 120 can implement, execute, and/or control (e.g., manage) the adaptive filter function 118, and/or other functions, components, and/or operations of the adaptive noise canceler component 102, based at least in part on the information or instructions obtained from the data store 122.

In some embodiments, the adaptive noise canceler component 102 can comprise an internal reference signal 124 that can be provided to (e.g., applied or input to) an input of the filter component 114 for processing or filtering of such internal reference signal 124, as controlled by the controller component 116, wherein the filtered reference signal (e.g., noise cancellation signal or error cancellation signal) can be utilized by the adaptive noise canceler component 102 to facilitate canceling (e.g., adaptively canceling) noise from sensor signals received from the sensor component 104, such as described herein. In certain embodiments, the internal reference signal 124 can be set to a defined constant value (e.g., a defined constant value of one (e.g., a binary, logic, or digital value of one)).

When the adaptive noise canceler component 102 receives the sensor signal from the sensor component 104, the sensor signal can be received by the positive (+) input of the differencing component 112 (e.g., subtractive summing component or node), wherein the sensor signal can comprise a signal portion that comprises the sensor data and a noise portion that comprises the noise (e.g., bias, drift, and/or other noise) in the sensor signal. The differencing component 112 can output, from an output port of the differencing component 112, an output signal that can be based at least in part on the sensor signal, as processed (e.g., modified or denoised) by the differencing component 112.

The output signal from the differencing component 112, in addition to being output from the adaptive noise canceler component 102 (e.g., to the AI component 106 and/or associated model 110), can be fed back (e.g., communicated) to the controller component 116 (e.g., to the adaptive filter function 118 of the controller component 116). The adaptive filter function 118 (and/or the processor component 120 implementing the adaptive filter function 118 and/or associated adaptive filter algorithm) can analyze the feedback signal (e.g., the output signal fed back to the controller component 116), and, based at least in part on the results of analyzing the feedback signal (and application of the adaptive filter function 118 and/or associated algorithm), can estimate or determine an error (e.g., an amount of error) in or associated with the feedback signal, wherein the error can correspond to, can be indicative of, or can be representative of the noise (e.g., the amount of noise, such as bias, drift, and/or other noise) in the sensor signal. For instance, the error in the sensor signal can relate to or can be indicative of the bias, drift, or direct current (DC) level in the sensor signal. Also, based at least in part on the results of analyzing the feedback signal (and application of the adaptive filter function 118 and/or associated algorithm), the adaptive filter function 118 (and/or the processor component 120) can determine a weight value (e.g., a bias weight) that can be applied at the filter component 114 to facilitate generating a noise cancellation signal (e.g., an error correction signal) that can be applied at the differencing component 112 to cancel the noise in the sensor signal. For instance, the adaptive filter function 118 (and/or the processor component 120) can determine a weight value that can match or correspond to the noise (e.g., bias, drift, or DC level) that is to be canceled in the sensor signal. It is noted that, because it is not necessary to match the phase of the signal, the adaptive filter function 118 (and/or the processor component 120) can utilize only one weight value (e.g., another weight value with regard to the phase of the signal is not necessary).

In accordance with various embodiments, to facilitate estimating the error in or associated with the feedback signal, determining a filtering and/or a weight value (e.g., bias weight value) to utilize to facilitate canceling the noise in the sensor signal, and/or generating a control signal relating to (e.g., indicative of or corresponding to) or comprising the weight value, the adaptive filter function 118 can be or can comprise, for example, a least mean squares (LMS) function and/or algorithm, another type of LMS-based function and/or algorithm (e.g., a normalized LMS (NMLS), a signed error LMS (SLMS), a variable LMS (VLMS), an affine projection, an affine projection sign, or other type of affine projection-based function and/or algorithm), a recursive least squares (RLS) function and/or algorithm, another type of RLS-based function and/or algorithm (e.g., a lattice RLS (LRLS) or a normalized LRLS (NLRLS) function and/or algorithm), a Kalman or Kalman-based function and/or algorithm, and/or another desired type of adaptive filtering function and/or algorithm.

The adaptive filter function 118 (and/or the processor component 120) can communicate the control signal, comprising or corresponding to the desired weight value, to the filter component 114. The filter component 114 can adaptively adjust the filter based at least in part on the control signal. Accordingly, the filter component 114 can filter or modify the internal reference signal 124, which can be input to the filter component 114, based at least in part on the adapted or adjusted filter, to generate a filtered signal, which can be the noise cancellation signal. The filter component 114 can be associated with (e.g., communicatively and/or electronically connected to) the negative (−) input of the differencing component 112. The filter component 114 can communicate the noise cancellation signal to the negative (−) input of the differencing component 112. The differencing component 112 can cancel, filter out, or remove (e.g., subtract) the noise from the sensor signal that is input to the positive (+) input of the differencing component 112, based at least in part on the noise cancellation signal input to the negative (−) input of the differencing component 112, to generate a denoised sensor signal as an output of the differencing component 112 and the adaptive noise canceler component 102. For example, the differencing component 112 can subtract a value of the noise cancellation signal from the sensor signal value of the sensor signal to generate the denoised sensor signal that can have a denoised value that can be (or at least substantially can be) (e.g., can correspond to, can be indicative of, or can be representative of) the sensor data (e.g., sensor data values or measurements) that was contained in the original sensor signal received and processed by the adaptive noise canceler component 102.

The adaptive noise canceler component 102, via its output port (e.g., the interface component (I/F) 126 of the adaptive noise canceler component 102), can be configured (e.g., the interface component can be configured) to communicate the denoised sensor signal, comprising the sensor data, to the input of the AI component 106 and/or the input of the model 110 to initiate, enable, and/or facilitate training of the model 110 (and/or an associated AI-based function). The controller component 116 can continue to monitor the output signal fed back to the controller component 116. If and as the controller component 116 (e.g., the adaptive filter function 118 and/or the processor component 120) detects any changes in the output signal (e.g., any error or noise) in the sensor signals being received by the adaptive noise canceler component 102 from the sensor component 104 (e.g., due to a change in bias and/or drift behavior of the sensor component 104 and associated sensor signals), the controller component 116 can estimate the error or noise associated with the sensor signal under consideration; determine a desirable weight value to utilize to facilitate canceling the noise in the sensor signal; generate a desirable (e.g., suitable, usable, enhanced, or optimal) control signal relating to (e.g., indicative of or corresponding to) or comprising the weight value; adapt the filter of the filter component 114, based at least in part on the control signal, to facilitate generating a noise cancellation signal as an output from the filter component 114; and apply the noise cancellation signal to the differencing component 112 to cancel or facilitate canceling the noise in the sensor signal to generate a denoised sensor signal as an output from the adaptive noise canceler component 102 (e.g., via the interface component 126) for input to the AI component 106 and/or model 110, such as described herein.

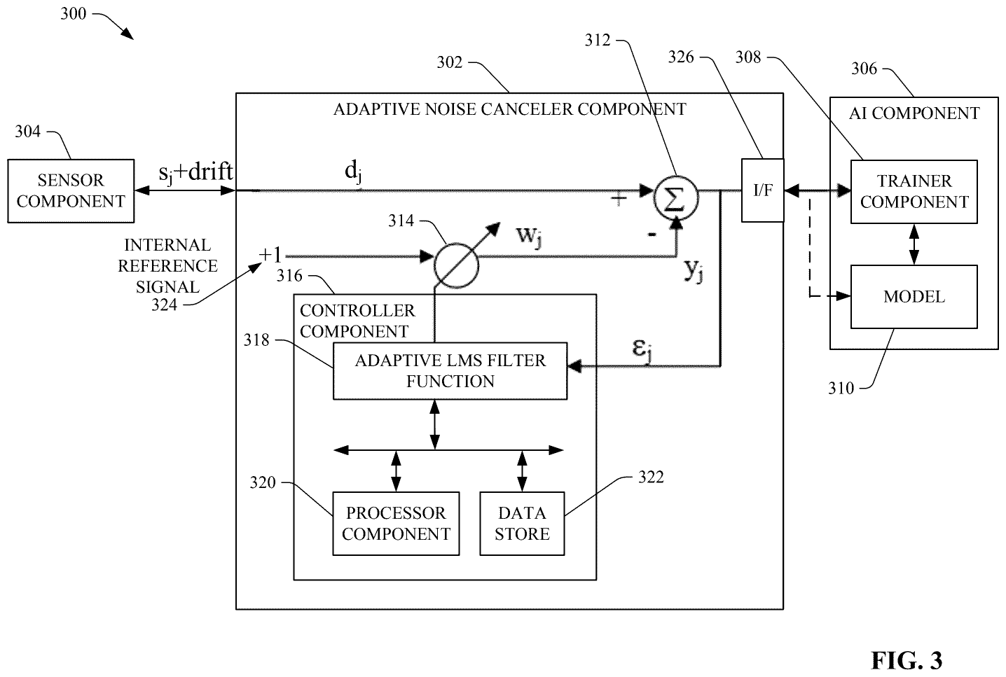

Referring to FIG. 3, FIG. 3 illustrates a diagram of a non-limiting example system 300 that can comprise an adaptive noise canceler component that can employ an LMS function and/or algorithm to facilitate desirably and adaptively canceling noise in a sensor signal received from a sensor component to generate a denoised sensor signal that can be provided to an AI-based model to facilitate training and operation (e.g., adaptive training and operation) of the AI-based model, in accordance with various aspects and embodiments of the disclosed subject matter. The system 300 can comprise an adaptive noise canceler component 302 that can have an input (e.g., input port) that can be associated with (e.g., communicatively and/or electronically connected to) a sensor component 304 (e.g., an output port of the sensor component 304). The sensor component 304 can be or can comprise a sensor that can have sensor-related functionality, such as described herein. The system 300 also can comprise an AI component 306, which can comprise the trainer component 308 and model 310, and can comprise AI component-related functionality, such as described herein.

The adaptive noise canceler component 302 can be same or similar in functionality as or to the adaptive noise canceler component 102 described with regard to the system 100 and FIG. 1, except that the adaptive noise canceler component 302 can involve embodiments where the adaptive noise canceler component 302 can utilize the LMS function and/or LMS algorithm to facilitate detecting noise in sensor signals received from the sensor component 304 and canceling such noise to generate a denoised output signal (e.g., denoised sensor signal) that can be communicated from the output port of the adaptive noise canceler component 302 to the input port of the AI component 306 or model 310 (whereas the adaptive noise canceler component 102 of the system 100 can utilize a desired adaptive filter function and/or adaptive filter algorithm that can be LMS-based, RLS-based, or another adaptive filter function or algorithm type, such as described herein). The adaptive noise canceler component 302 can comprise a differencing component 312, a filter component 314, and a controller component 316 (also referred to herein as an adaptive noise canceler controller component). The controller component 316 can comprise an adaptive LMS filter function 318, a processor component 320, and a data store 322. The differencing component 312, filter component 314, controller component 316 adaptive LMS filter function 318, processor component 320, and data store 322 can comprise same or similar functionality and/or features as respective same or similarly named components, such as described herein.

The adaptive noise canceler component 302 also can comprise an internal reference signal 324 that can be provided to (e.g., applied or input to) an input of the filter component 314 for processing or filtering of such internal reference signal 324, as controlled by the controller component 316, wherein the filtered reference signal (e.g., noise cancellation signal or error cancellation signal) can be utilized by the adaptive noise canceler component 302 to facilitate canceling noise from sensor signals received from the sensor component 304, such as described herein. In certain embodiments, the internal reference signal 324 can be set to a defined constant value (e.g., a defined constant value of one (e.g., a binary, logic, or digital value of one)).

When the adaptive noise canceler component 302 receives a sensor signal from the sensor component 304, the sensor signal can be received by the positive (+) input of the differencing component 312. The sensor signal (e.g., sⱼ+drift) can comprise a signal portion (e.g., sⱼ) that comprises the sensor data and a noise portion (e.g., drift (or other noise)) that comprises the noise (e.g., bias, drift, and/or other noise) in the sensor signal (e.g., the sensor signal also can be referred to as the primary input, dⱼ). The differencing component 312 can output, from an output port of the differencing component 312, an output signal that can be based at least in part on the sensor signal, as processed (e.g., modified or denoised) by the differencing component 312, such as described herein.

The output signal from the differencing component 312, in addition to being output from the adaptive noise canceler component 302 (e.g., to the AI component 306 and/or associated model 310), can be fed back (e.g., communicated) to the controller component 316 (e.g., to the adaptive LMS filter function 318 of the controller component 316). The adaptive LMS filter function 318 (and/or the processor component 320 implementing the adaptive LMS filter function 318 and/or associated LMS algorithm) can analyze the feedback signal (e.g., error signal, εⱼ), and, based at least in part on the results of analyzing the feedback signal (and application of the adaptive LMS filter function 318 and/or associated LMS algorithm), can estimate or determine an error (e.g., an amount of error) in or associated with the feedback signal (e.g., error signal, εⱼ), wherein the error can correspond to (e.g., can be indicative or representative of) the noise (e.g., the amount of noise, such as bias, drift, and/or other noise) in the sensor signal, such as described herein. For example, the error in the sensor signal can relate to or can be indicative of the bias, drift, or DC level in the sensor signal. Also, based at least in part on the results of analyzing the feedback signal (and application of the adaptive LMS filter function 318 and/or associated LMS algorithm), the adaptive LMS filter function 318 (and/or the processor component 320) can determine a weight value (e.g., a bias weight, wⱼ) that can be applied at the filter component 314 to facilitate generating a noise cancellation signal (e.g., an error correction signal) that can be applied at (e.g., communicated or supplied to) the differencing component 312 to cancel the noise in the sensor signal, such as described herein. For instance, the adaptive LMS filter function 318 (and/or the processor component 320) can determine a weight value (e.g., wⱼ) that can match or correspond to the noise (e.g., bias, drift, or DC level) that is to be canceled in the sensor signal. It is noted that, because it is not necessary to match the phase of the signal, the adaptive LMS filter function 318 (and/or the processor component 320) can utilize only one weight value.

The adaptive LMS filter function 318 (and/or the processor component 320) can communicate the control signal, comprising or corresponding to the desired weight value, to the filter component 314. The filter component 314 can adaptively adjust the filter based at least in part on the control signal. Accordingly, the filter component 314 can filter or modify the internal reference signal 324, which can be input to the filter component 314, based at least in part on the adapted or adjusted filter, to generate a filtered signal (e.g., yⱼ), which can be the noise cancellation signal, such as described herein. The filter component 314 can be associated with (e.g., communicatively and/or electronically connected to) the negative (−) input of the differencing component 312. The filter component 314 can communicate the noise cancellation signal to the negative (−) input of the differencing component 312. The differencing component 312 can cancel, filter out, or remove (e.g., subtract) the noise from the sensor signal that is input to the positive (+) input of the differencing component 312, based at least in part on the noise cancellation signal input to the negative (−) input of the differencing component 312, to generate a denoised sensor signal as an output of the differencing component 312 and the adaptive noise canceler component 302. For example, the differencing component 312 can subtract a value of the noise cancellation signal from the sensor signal value of the sensor signal to generate the denoised sensor signal that can have a denoised value that can be (or at least substantially can be) (e.g., can correspond to, can be indicative of, or can be representative of) the sensor data (e.g., sensor data values or measurements) that was contained in the original sensor signal received and processed by the adaptive noise canceler component 302.

The adaptive noise canceler component 302, via its output port (e.g., the interface component of the adaptive noise canceler component 302), can communicate the denoised sensor signal, comprising the sensor data, to the input of the AI component 306 and/or the input of the model 310 to initiate, enable, and/or facilitate training of the model 310 (and/or an associated AI-based function). The controller component 316 can continue to monitor the output signal fed back (e.g., the error signal, εⱼ, fed back) to the controller component 316. If and as the controller component 316 (e.g., the adaptive LMS filter function 318 and/or the processor component 320) detects any changes in the output signal (e.g., any error or noise) in the sensor signals being received by the adaptive noise canceler component 302 from the sensor component 304 (e.g., due to a change in bias and/or drift behavior of the sensor component 304 and associated sensor signals), the controller component 316 can estimate the error or noise associated with the sensor signal under consideration; determine a desirable weight value to utilize to facilitate canceling the noise in the sensor signal utilizing the adaptive LMS filter function 318; generate a desirable (e.g., suitable, usable, enhanced, or optimal) control signal relating to (e.g., indicative of or corresponding to) or comprising the weight value; adapt the filter of the filter component 314, based at least in part on the control signal, to facilitate generating a noise cancellation signal as an output from the filter component 314 (e.g., via the interface component 326 of the adaptive noise canceler component 302); and apply the noise cancellation signal to the differencing component 312 to cancel or facilitate canceling the noise in the sensor signal to generate a denoised sensor signal as an output from the adaptive noise canceler component 302 for input to the AI component 306 and/or model 310, such as described herein.

Further aspects of the adaptive LMS filter function 318 and associated LMS algorithm can be described as follows. The use of a bias weight in an adaptive filter, such as the filter component 314, to cancel low-frequency drift and/or other noise in the primary input, dⱼ (e.g., the input sensor signal) can be a particular case of notch filtering with the notch at zero frequency. The controller component 316, employing the adaptive LMS filter function 318 and associated LMS algorithm, can utilize or incorporate the bias weight to cancel the bias or DC level, and accordingly, can be fed with the internal reference signal 324 set to a constant value of one. The controller component 316, employing the adaptive LMS filter function 318 and associated LMS algorithm, can update (e.g., modify or adjust) to match the DC level or bias to be canceled with regard to the sensor signal being processed by the adaptive noise canceler component 302. As disclosed, since it is not necessary to match the phase of the signal, the adaptive LMS filter function 318 (and/or the processor component 320) can utilize only one weight value.

The transfer function from the primary input, dⱼ, to the denoised sensor signal output from the adaptive noise canceler component 302 can be derived or obtained from the following equations. The output, yⱼ, of the filter component 314 (e.g., adaptive filter component) can be expressed by the following equation: yⱼ=wⱼ·1=wⱼ.

The adaptive LMS filter function 318 (and/or the processor component 320) can update (e.g., can determine or calculate an update to) the bias weight, w, for example, in accordance with the following LMS update equation:

$$\begin{matrix}{w}_{j + 1} = {w}_{j} + 2 μ ( {ε}_{j} \cdot 1 ) ⇒ \\ {y}_{j + 1} = {y}_{j} + 2 μ ( {d}_{j} - {y}_{j} ) \\ = ( 1 - 2 μ ) {y}_{j} + 2 μ {d}_{j} .\end{matrix}$$

Applying the z-transform to both sides of the above equation can yield the steady-state solution, as presented, for example, in the following equation:

$$Y ( z ) = \frac{2 μ}{z - ( 1 - 2 μ )} D ( z ) .$$

The z-transform of the error signal, εⱼ, can be determined, for example, in accordance with the following equation:

$$\begin{matrix}E ( z ) = D ( z ) - y ( z ) \\ = \frac{z - 1}{z - ( 1 - 2 μ )} D ( z ) .\end{matrix}$$

Based on the foregoing, the transfer function from the primary input, dⱼ, to the denoised sensor signal output from the adaptive noise canceler component 302 can be expressed, for example, in accordance with the following equation:

$$H ( z ) = \frac{E ( z )}{D ( z )} = \frac{z - 1}{z - ( 1 - 2 μ )} .$$

This can show that the bias-weight filter can be a high pass filter with a zero on the unit circle at zero frequency and a pole on the real axis at a distance of 2μ to the left of the zero. The smaller the μ, the closer is the location of the pole and the zero, and consequently, the notch can be at zero frequency, such that, for example, only the DC level is removed from the input signal. The adaptive noise canceler component 302, employing the single-weight noise cancellation described herein, can act as a high-pass filter that can be capable of canceling (e.g., removing or filtering out) the bias (e.g., a constant bias) and the drift (e.g., a relatively slowly varying drift) from the sensor signal (e.g., the primary input). For example, if the bias level drifts and such drift is relatively slow, the controller component 316, employing the adaptive LMS filter function 318 and associated LMS algorithm, can adaptively adjust the bias weight to track and cancel such drift from the sensor signal. In some embodiments, the adaptive noise canceler component 302 may use the bias weight, along with other weights to facilitate canceling bias and/or drift from sensor signals concurrently with canceling periodic or stochastic interference.

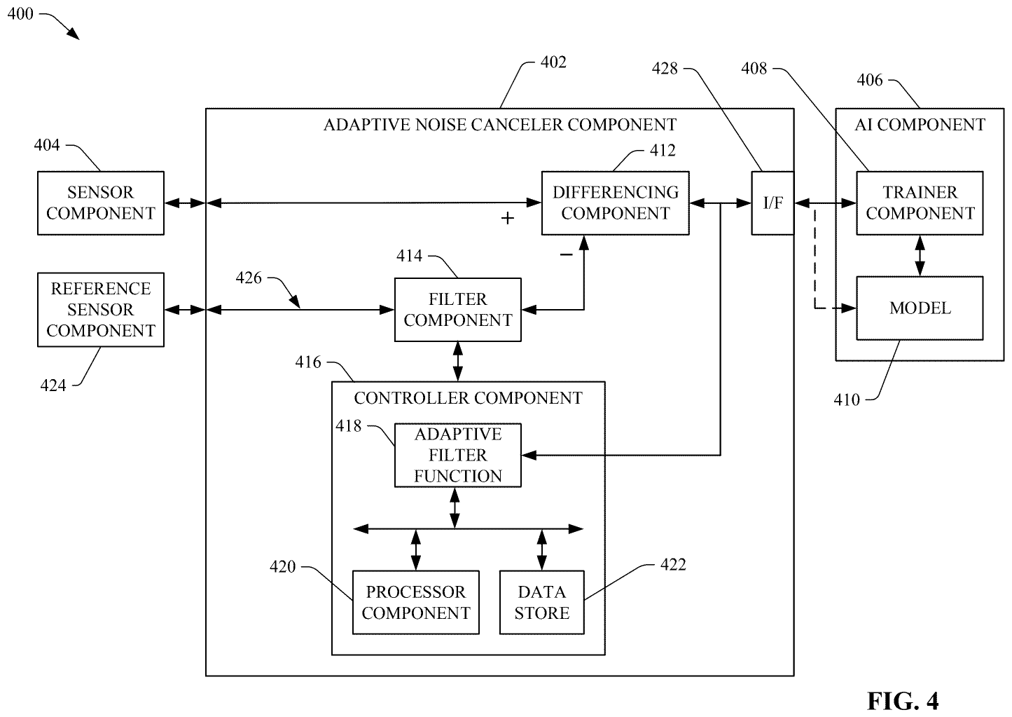

Referring to FIG. 4, FIG. 4 depicts a block diagram of a non-limiting example system 400 that can comprise an adaptive noise canceler component that can desirably and adaptively cancel noise in a sensor signal received from a sensor component, based at least in part on an external reference signal and an adaptive filter function, to generate a denoised sensor signal that can be provided to an AI-based model to facilitate training and operation (e.g., adaptive training and operation) of the AI-based model, in accordance with various aspects and embodiments of the disclosed subject matter. The system 400 can comprise an adaptive noise canceler component 402 that can have an input (e.g., input port) that can be associated with (e.g., communicatively and/or electronically connected to) a sensor component 404 (e.g., an output port of the sensor component 404). The sensor component 404 can be or can comprise one or more sensors, such as described herein. The sensor(s) of the sensor component 404 can be any type of sensor that can experience and/or can be susceptible to noise or interference, such as, for example, bias and/or drift behaviors, and/or environmental, interference, and/or other behaviors or conditions, in or associated with the sensor or signals generated by the sensor(s). In some embodiments, the sensor component 404 can be a MEMS or semiconductor sensor component that can comprise one or more MEMS or semiconductor sensors that can be formed using MEMS technology. In certain embodiments, the adaptive noise canceler component 402, or certain components thereof, can be formed using MEMS technology.

In some embodiments, an output (e.g., output port) of the adaptive noise canceler component 402 can be associated with (e.g., communicatively and/or electronically connected to and/or interfaced with) an input of an AI component 406. In certain embodiments, the AI component 406 can comprise a trainer component 408 and one or more AI-based models, such as AI-based model 410 (the AI-based models also can be referred to herein as models). The model 410 can be, for example, an AI model, ML model, neural network model, graph mining model, SVM classifier model, other type of classifier model, decision tree model, or other type of AI-based model. The model 410 can be trained to perform AI-based analysis on data to generate data results based at least in part on the AI-based analysis. For instance, the model 410 (e.g., trained model) can receive input data. The model 410 (and/or an AI-based function of the AI component 406) can perform an AI-based analysis on the input data and/or other data, and can generate data results as an output from the model 410 based at least in part on the results of the AI-based analysis. The data results can comprise, for example, prediction data, probability data, determination or decision data, and/or other data that can be determined and/or generated by the model 410 based at least in part on the input data input to the model 410, the training of the model 410, and the AI-based analysis performed on the input data and/or other data by the model 410 (and/or the AI-based function).

As disclosed, existing systems and techniques for training AI-based models using sensor signals can be deficient in a number of ways, including that certain sensors and sensor signals can experience noise or interference (e.g., bias, drift, environmental-related, interference-related, and/or other behaviors), which can negatively impact (e.g., render inaccurate) the sensor data (e.g., sensor measurements or other sensor data) in the sensor signals, and which can thereby result in undesirable (e.g., inaccurate, unacceptable, unsuitable, inefficient, or suboptimal) training of the AI-based models, and undesirable (e.g., inaccurate, unacceptable, unsuitable, inefficient, or suboptimal) performance of and output data (e.g., data results) generated by the AI-based models. The disclosed subject matter (e.g., the system 400, and the techniques and methods, described herein) can overcome the various issues and deficiencies of existing systems, methods, and techniques with regard to providing data to AI-based models and training AI-based models using such data.

In that regard, the system 400 can employ the adaptive noise canceler component 402 that can be configured to desirably (e.g., automatically, dynamically, suitably, quickly, efficiently, enhancedly, and/or optimally) process a sensor signal, comprising sensor data and noise, that can be received from the sensor component 404 and adaptively cancel the noise (e.g., noise relating to and/or caused by bias and/or drift, environmental conditions, and/or other conditions or interference associated with the sensor component 404) that can be in the sensor signal to generate a denoised or filtered sensor signal that can comprise the sensor data of the sensor signal, but can have the noise portion (or at least a desirably substantial amount of the noise) of the sensor signal canceled (e.g., removed or filtered out). The adaptive noise canceler component 402 can communicate (e.g., in real time or near real time) the denoised sensor signal, via the output port (e.g., interface component) of the adaptive noise canceler component 402, to the input of the AI component 406 and/or the input of the model 410 to facilitate training of the model 410.

The model 410 can be desirably trained (e.g., by the trainer component 408) based at least in part on the denoised sensor signal(s), comprising the sensor data, received from the adaptive noise canceler component 402. As a result of the adaptive noise canceler component 402 canceling the noise in the sensor signals received from the sensor component 404 and providing denoised sensor signals, comprising the sensor data, to the model 410 for training of the model 410, the training of the model 410 can be enhanced (e.g., improved) and can be performed more accurately and efficiently, and the data results produced by the trained model 410 can be enhanced (e.g., can be improved, more accurate, and/or more efficiently obtained), as compared to existing systems and techniques for training models and using trained models.

With further regard to the features and functions of the adaptive noise canceler component 402, in some embodiments, the adaptive noise canceler component 402 can comprise a differencing component 412, a filter component 414 (e.g., an adaptive or adjustable filter), and a controller component 416 (also referred to herein as an adaptive noise canceler controller component). In certain embodiments, the controller component 416 can comprise an adaptive filter function 418 that can be utilized to facilitate estimating or determining noise in a sensor signal received from the sensor component 404 and canceling the noise from the sensor signal to generate a denoised sensor signal, such as described herein. In some embodiments, the controller component 416 can comprise or can be associated with (e.g., communicatively and/or electronically connected to) a processor component 420 and/or a data store 422 that can be associated with the processor component 420. The data store 422 can comprise various types of information, including information relating to the adaptive filter function 418, processing of sensor signals, canceling noise from sensor signals, instructions, control-related information, and/or other desired information. The processor component 420 can implement, execute, and/or control (e.g., manage) the adaptive filter function 418, and/or other functions, components, and/or operations of the adaptive noise canceler component 402, based at least in part on the information or instructions obtained from the data store 422.

In some embodiments, the system 400 can comprise a reference sensor component 424 that can be or can comprise one or more sensors that can sense conditions (e.g., environmental conditions or other conditions) and/or interference associated with the sensor component 404. For instance, the one or more sensors of the reference sensor component 424 can comprise a temperature sensor, a humidity sensor, an air pressure sensor, an RF interference sensor, and/or other desired sensor that can sense, detect, and/or measure temperature, humidity, air pressure, RF interference, and/or other conditions or interference associated with (e.g. negatively impacting or affecting; and/or in proximity to) the sensor component 404 and sensor signals generated by the sensor component 404, wherein such conditions or interference can cause undesirable noise in the sensor signals generated by the sensor component 404. In accordance with various embodiments, the adaptive noise canceler component 402 can cancel (e.g., adaptively cancel) noise from sensor signals received from the sensor component 404, wherein such noise not only includes noise resulting from sensor bias and/or drift behaviors of the sensor component 404, but also other noise resulting from conditions or interference associated with the sensor component 404 as detected and/or measured by the reference sensor component 424.

In certain embodiments, the adaptive noise canceler component 402 can receive an external reference signal 426, such as a reference sensor signal or other signal generated by the reference sensor component 424 based at least in part on the reference sensor signal, from the reference sensor component 424. In some embodiments, the external reference signal 426 can be provided to (e.g., applied or input to) the input of the filter component 414 for processing or filtering of such external reference signal 426, as controlled by the controller component 416, wherein the filtered reference signal (e.g., noise cancellation signal or error cancellation signal) generated and output by the filter component 414 can be utilized by the adaptive noise canceler component 402 to facilitate canceling (e.g., adaptively canceling) noise from sensor signals received from the sensor component 404, such as described herein. In some embodiments, the external reference signal 426 can have an external reference signal value that can vary based at least in part on (e.g., corresponding to) variations or changes in the conditions associated with the sensor component 404 and sensor signals, as such variations or changes in the conditions are sensed, detected, and/or measured by the one or more sensors of the reference sensor component 424 and reflected in the external reference signal 426 generated as an output by the reference sensor component 424. In certain embodiments, the external reference signal 426 can have an external reference signal value that can range from 0 to 1.0, and in certain other embodiments, can have an external reference signal value that can range from 0 to a value greater than 1.0.

When the adaptive noise canceler component 402 receives the sensor signal from the sensor component 404, the sensor signal can be received by the positive (+) input of the differencing component 412 (e.g., subtractive summing component or node), wherein the sensor signal can comprise a signal portion that comprises the sensor data and a noise portion that comprises the noise (e.g., bias, drift, and/or other noise) in the sensor signal. The differencing component 412 can output, from an output port of the differencing component 412, an output signal that can be based at least in part on the sensor signal, as processed (e.g., modified or denoised) by the differencing component 412.

The output signal from the differencing component 412, in addition to being output from the adaptive noise canceler component 402 (e.g., to the AI component 406 and/or associated model 410), can be fed back (e.g., communicated) to the controller component 416 (e.g., to the adaptive filter function 418 of the controller component 416). The adaptive filter function 418 (and/or the processor component 420 implementing the adaptive filter function 418 and/or associated adaptive filter algorithm) can analyze the feedback signal (e.g., the output signal fed back to the controller component 416), and, based at least in part on the results of analyzing the feedback signal (and application of the adaptive filter function 418 and/or associated algorithm), can estimate or determine an error (e.g., an amount of error) in or associated with the feedback signal, wherein the error can correspond to, can be indicative of, or can be representative of the noise (e.g., the amount of noise, such as noise relating to noise relating to and/or caused by bias and/or drift, environmental conditions, and/or other conditions or interference associated with the sensor component 404) in the sensor signal. For instance, the error in the sensor signal can relate to or can be indicative of the bias, drift, or DC level in the sensor signal, and/or can relate to or can be indicative of noise caused by environmental conditions and/or other conditions or interference associated with (e.g., in proximity to and impacting performance of) the sensor component 404.

In certain embodiments, based at least in part on the results of analyzing the feedback signal (and application of the adaptive filter function 418 and/or associated algorithm), the adaptive filter function 418 (and/or the processor component 420) can determine a weight value (e.g., a bias weight) that can be applied at the filter component 414 to facilitate generating a noise cancellation signal (e.g., an error correction signal) that can be applied at the differencing component 412 to cancel the noise in the sensor signal. For instance, the adaptive filter function 418 (and/or the processor component 420) can determine a weight value that can match or correspond to the noise (e.g., bias, drift, or DC level; and/or noise caused by environmental conditions or other conditions) that is to be canceled in the sensor signal. It is noted that, in some embodiments, because it is not necessary to match the phase of the signal, the adaptive filter function 418 (and/or the processor component 420) can utilize only one weight value (e.g., another weight value with regard to the phase of the signal is not necessary).

In accordance with various embodiments, to facilitate estimating the error in or associated with the feedback signal, determining a filtering and/or a weight value (e.g., bias weight value or other weight value) to utilize to facilitate canceling the noise in the sensor signal, and/or generating a control signal relating to (e.g., indicative of or corresponding to) or comprising the weight value, the adaptive filter function 418 can be or can comprise, for example, an LMS-based function and/or algorithm, an RLS-based function and/or algorithm, a Kalman or Kalman-based function and/or algorithm, and/or another desired type of adaptive filtering function and/or algorithm, such as described herein.

The adaptive filter function 418 (and/or the processor component 420) can communicate the control signal, comprising or corresponding to the desired weight value, to the filter component 414. The filter component 414 can adaptively adjust the filter based at least in part on the control signal. Accordingly, the filter component 414 can filter or modify the external reference signal 426, which can be input to the filter component 414, based at least in part on the adapted or adjusted filter, to generate a filtered signal, which can be the noise cancellation signal that can have a noise cancellation signal value. The filter component 414 can be associated with (e.g., communicatively and/or electronically connected to) the negative (−) input of the differencing component 412. The filter component 414 can communicate the noise cancellation signal to the negative (−) input of the differencing component 412. The differencing component 412 can cancel, filter out, or remove (e.g., subtract) the noise from the sensor signal that is input to the positive (+) input of the differencing component 412, based at least in part on the noise cancellation signal (e.g., the noise cancellation signal value) input to the negative (−) input of the differencing component 412, to generate a denoised sensor signal as an output of the differencing component 412 and the adaptive noise canceler component 402. For example, the differencing component 412 can subtract the noise cancellation signal value of the noise cancellation signal from the sensor signal value of the sensor signal to generate the denoised sensor signal that can have a denoised value that can be (or at least substantially can be) (e.g., can correspond to, can be indicative of, or can be representative of) the sensor data (e.g., sensor data values or measurements) that was contained in the original sensor signal received and processed by the adaptive noise canceler component 402.

The adaptive noise canceler component 402, via its output port (e.g., the interface component 428 of the adaptive noise canceler component 402), can be configured (e.g., the interface component 428 can be configured) to communicate the denoised sensor signal, comprising the sensor data, to the input of the AI component 406 and/or the input of the model 410 to initiate, enable, and/or facilitate training of the model 410 (and/or an associated AI-based function). The controller component 416 can continue to monitor the output signal fed back to the controller component 416. If and as the controller component 416 (e.g., the adaptive filter function 418 and/or the processor component 420) detects any changes in the output signal (e.g., any error or noise) in the sensor signals being received by the adaptive noise canceler component 402 from the sensor component 404 (e.g., due to a change in bias and/or drift behavior of the sensor component 404 and associated sensor signals, and/or a change in the environmental and/or other conditions associated with the sensor component 404 and associated sensor signals), the controller component 416 can estimate the error or noise associated with the sensor signal under consideration; determine a desirable weight value to utilize to facilitate canceling the noise in the sensor signal; generate a desirable (e.g., suitable, usable, enhanced, or optimal) control signal relating to (e.g., indicative of or corresponding to) or comprising the weight value; adapt the filter of the filter component 414, based at least in part on the control signal, to facilitate generating a noise cancellation signal as an output from the filter component 414 (e.g., based at least in part on the control signal, the weight value, and/or the external reference signal 426); and apply the noise cancellation signal to the differencing component 412 to cancel or facilitate canceling the noise in the sensor signal to generate a denoised sensor signal as an output from the adaptive noise canceler component 402 (e.g., via the interface component 428) for input to the AI component 406 and/or model 410, such as described herein.

With further regard to the processor component (e.g., 120, 320, or 420) described herein, the processor component (e.g., 120, 320, or 420) can work in conjunction with the other components (e.g., sensor component (e.g., 104, 304, or 404), AI component (e.g., 106, 306, or 406), model (e.g., 110, 310, or 410), differencing component (e.g., 112, 312, or 412), filter component (e.g., 114, 314, or 414), controller component (e.g., 116, 316, or 416), adaptive filter function (e.g., adaptive filter function 118, adaptive LMS filter function 318, or adaptive filter function 418), data store (e.g., 122, 322, or 422), interface component (e.g., 126, 328, or 428), and/or other components) to facilitate performing the various functions of the systems (e.g., 100, 300, or 400) described herein. The processor component (e.g., 120, 320, or 420) can employ one or more processors (e.g., CPUs), microprocessors, controllers, or microcontrollers that can process data, such as information relating to sensor signals, denoised sensor signals, reference signals, adaptive filtering, adaptive filter functions, error or noise, weight values, AI-based models or functions, parameter values, mappings, instructions, code, policies and rules, defined signal processing criteria, traffic flows, signaling, algorithms (e.g., adaptive filtering algorithms, LMS-based algorithms, RLS-based algorithms, AI-based algorithms, or other algorithms, as disclosed, defined, recited, or indicated herein by the methods, systems, and techniques described herein), protocols, interfaces, tools, and/or other information, to facilitate operation of the system (e.g., 100, 300, or 400), as more fully disclosed herein, and control data or signal flow between the respective electronic components of the system (e.g., 100, 300, or 400) described herein, and/or between the electronic components of the system (e.g., 100, 300, or 400) and other electronic components or devices (e.g., AI components, sensor components, devices, computers, or other components) associated with the system (e.g., 100, 300, or 400), and/or between the electronic components of the system (e.g., 100, 300, or 400) and/or applications associated with the system (e.g., 100, 300, or 400).

With further regard to the data store (e.g., 122, 322, or 422), the data store (e.g., 122, 322, or 422) can store data structures (e.g., user data, metadata), code structure(s) (e.g., modules, objects, hashes, classes, procedures) or instructions, information relating to sensor signals, denoised sensor signals, reference signals, adaptive filtering, adaptive filter functions, error or noise, weight values, AI-based models or functions, parameter values, mappings, instructions, code, policies and rules, defined signal processing criteria, traffic flows, signaling, algorithms (e.g., adaptive filtering algorithms, LMS-based algorithms, RLS-based algorithms, AI-based algorithms, or other algorithms, as disclosed, defined, recited, or indicated herein by the methods, systems, and techniques described herein), protocols, interfaces, tools, and/or other information, to facilitate controlling operations associated with the system (e.g., 100, 300, or 400). In an aspect, the processor component (e.g., 120, 320, or 420) can be functionally coupled (e.g., through a memory bus) to the data store (e.g., 122, 322, or 422) in order to store and retrieve information desired to operate and/or confer functionality, at least in part, to the system (e.g., 100, 300, or 400) and its components, and the data store (e.g., 122, 322, or 422), and/or substantially any other operational aspects of the system (e.g., 100, 300, or 400).

In accordance with various embodiments, the data store (e.g., 122, 322, or 422) can comprise volatile memory and/or nonvolatile memory. By way of example and not limitation, nonvolatile memory can include read only memory (ROM), programmable ROM (PROM), electrically programmable ROM (EPROM), electrically erasable ROM (EEPROM), or flash memory. Volatile memory can include random access memory (RAM), which can act as external cache memory. By way of example and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Memory of the disclosed aspects are intended to comprise, without being limited to, these and other suitable types of memory.

In some embodiments, the adaptive noise canceler component (e.g., 102, 302, or 402), the sensor component (e.g., 104, 304, or 404), and the AI component (e.g., 106, 306, or 406) can be combined, and connected and interfaced with each other, as a single product. In certain other embodiments, the adaptive noise canceler component (e.g., 102, 302, or 402) can be a separate product(s) from, and connectable and interfaceable with, the sensor component (e.g., 104, 304, or 404) and/or the AI component (e.g., 106, 306, or 406).

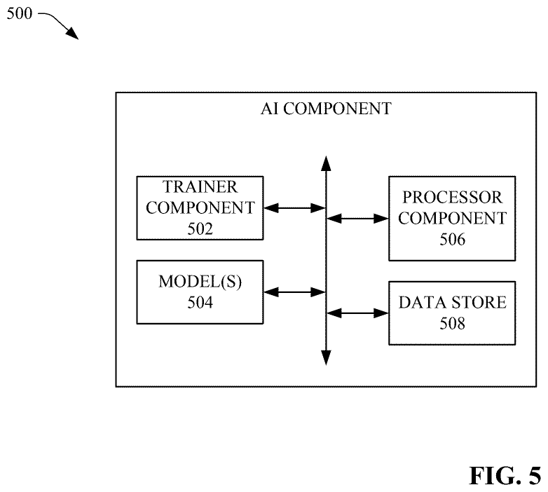

Referring to FIG. 5, FIG. 5 depicts a block diagram of a non-limiting example AI component 500 that can receive sensor signals (e.g., denoised sensor signals) from the adaptive noise canceler component and can employ an AI-based model(s) to perform an AI-based analysis on data, including the sensor signals (e.g., denoised sensor signals), to facilitate training of the AI-based model(s) and generating AI-based analysis results (e.g., inferences, probabilities, determinations, and/or other AI-based analysis results), in accordance with various aspects and embodiments of the disclosed subject matter. In accordance with various embodiments, the AI component 106 of the system 100, the AI component 306 of the system 300, and/or the AI component 406 of the system 400 can be the same as or similar to the AI component 500. In some embodiments, the AI component 500 can comprise a trainer component 502 and model(s) 504 (e.g., one or more AI-based models). In accordance with various embodiments, the AI component 500 can comprise or can be associated with a processor component 506 and a data store 508.

In certain embodiments, the AI component 500 (e.g., employing the model(s) 504) can perform AI-based analysis on data, such as sensor signals (e.g., denoised sensor signals), and/or information relating to sensor signals (e.g., tokenized and/or vectorized data, such as vector embeddings, that can be representative of the denoised sensor signals or other data), training of the model(s) 504, parameters, hyperparameters, processes, operations, functions, training procedures, and/or other features of the model(s), feedback and/or backpropagation relating to performance and/or training of the model(s), and/or other aspects or features associated with the model(s). In some embodiments, with regard to the model(s) 504, and depending on the type of model, the AI component 500 can input such information into the (trained) model(s) 504 for analysis by the model(s) 504 to update the model(s) 504 or to generate output data or results (e.g., AI-related data, and/or other data or results) based at least in part on the analysis of the input information. In certain embodiments, the AI component 500 (e.g., trainer component 502 or other component of the AI component 500) can pre-process the denoised sensor signals, other training or operational data, and/or other data to generate tokenized and/or vectorized data, such as vector embeddings, that can be representative of the denoised sensor signals, other training or operational data, or other data, and can be in a format and/or data representation that can be understood, processed, and analyzed by the AI-based model(s) 504.

In accordance with various embodiments, in connection with or as part of such AI-based analysis, the AI component 500 can employ, build (e.g., construct or create), and/or import, AI-based techniques and algorithms, AI models (e.g., untrained or trained models), ML models, neural networks (e.g., untrained or trained neural networks), transformer-based models, GPT-type models, SVM classifier models or other type(s) of classifier models, decision trees, Markov chains (e.g., trained Markov chains), graph mining, and/or other AI-based models to render and/or generate predictions, inferences, calculations, prognostications, estimates, derivations, forecasts, detections, and/or computations that can facilitate determining or learning data patterns in data, determining or learning a correlation, relationship, or causation between an item(s) of data and another item(s) of data (e.g., occurrence of the other item(s) of data or an event relating thereto), determining or learning a correlation, relationship, or causation between an event and another event (e.g., occurrence of another event), determining or learning about relationships between components or functions of or associated with the system (e.g., 100, 300, or 400), determining or learning characteristics or features relating to the sensor data (e.g., contained in the denoised sensor signals), performing other desired functions or operations, and/or automating one or more functions or features of the disclosed subject matter, as more fully described herein.

In accordance with various embodiments, the AI component 500 can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute) described herein with regard to the disclosed subject matter, the AI component 500 can examine the entirety or a subset of the data (e.g., sensor data contained in denoised sensor signals; other model training data; the feedback or backpropagation information; and/or other information, such as described herein) to which it is granted access and can provide for reasoning about or determine states of the system and/or environment from a set of observations as captured via events and/or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events and/or data.

Such determinations can result in the construction of new events or actions from a set of observed events and/or stored event data, whether or not the events are correlated in close temporal proximity, and whether the events and data come from one or several event and data sources. In certain embodiments, components (e.g., the AI component 500, the model(s) 504, and/or another component) disclosed herein can employ various classification (explicitly trained (e.g., via training data) as well as implicitly trained (e.g., via observing behavior, preferences, historical information, receiving extrinsic information, and so on)) schemes and/or systems (e.g., SVMs, neural networks, expert systems, Bayesian belief networks, fuzzy logic, data fusion engines, and so on) in connection with performing automatic and/or determined action in connection with the claimed subject matter. Thus, classification schemes and/or systems can be used to automatically learn and perform a number of functions, actions, and/or determinations.

In some embodiments, the AI component 500 can employ a classifier that can perform AI-based analysis on data. A classifier can map an input attribute vector, z=(z1, z2, z3, z4, . . . , zn), to a confidence that the input belongs to a class, as by f(z)=confidence (class). Such classification can employ a probabilistic and/or statistical-based analysis (e.g., factoring into the analysis utilities and costs) to determinate an action to be automatically performed. An SVM can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, and/or probabilistic classification models providing different patterns of independence, any of which can be employed. Classification as used herein also is inclusive of statistical regression that is utilized to develop models of priority.

With further regard to the processor component 506 and the data store 508, the processor component 506 can work in conjunction with the other components (e.g., the trainer component 502, the model(s), the data store 508, and/or other components) to facilitate performing the various functions of the AI component 500 described herein. The processor component 506 can employ one or more processors (e.g., CPUs), accelerators, graphics processing units (GPUs), application-specific integrated circuits (ASICs), microprocessors, controllers, or microcontrollers that can process data, such as information relating to sensor signals (e.g., denoised sensor signals, comprising sensor data), training data, tokenized or vectorized data (e.g., the tokenized and/or vectorized data, such as vector embeddings that can be representative of the denoised sensor signals or other data), AI-based models or functions, feedback and/or backpropagation information, parameter or hyperparameter values, mappings, instructions, code, policies and rules, the defined signal processing criteria, traffic flows, signaling, algorithms (e.g., AI-based algorithms or other algorithms, as disclosed, defined, recited, or indicated herein by the methods, systems, and techniques described herein), protocols, interfaces, tools, and/or other information, to facilitate operation of the AI component 500, as more fully disclosed herein, and control data or signal flow between the respective electronic components of the AI component 500 described herein, and/or between the electronic components of the AI component 500 and other electronic components or devices (e.g., the adaptive noise canceler component, sensor components, devices, computers, or other components) associated with the AI component 500, and/or between the electronic components of the AI component 500 and/or applications or services associated with the AI component 500.

In some embodiments, the data store 508 can store data structures (e.g., user data, metadata), code structure(s) (e.g., modules, objects, hashes, classes, procedures) or instructions, information relating to sensor signals (e.g., denoised sensor signals, comprising sensor data), training data, tokenized or vectorized data (e.g., the tokenized and/or vectorized data, such as vector embeddings that can be representative of the denoised sensor signals or other data), AI-based models or functions, feedback and/or backpropagation information, parameter or hyperparameter values, mappings, instructions, code, policies and rules, the defined signal processing criteria, traffic flows, signaling, algorithms (e.g., AI-based algorithms or other algorithms, as disclosed, defined, recited, or indicated herein by the methods, systems, and techniques described herein), protocols, interfaces, tools, and/or other information, to facilitate controlling operations associated with the AI component 500. In an aspect, the processor component 506 can be functionally coupled (e.g., through a memory bus) to the data store 508 in order to store and retrieve information desired to operate and/or confer functionality, at least in part, to the AI component 500 and its components, and the data store 508, and/or substantially any other operational aspects of the AI component 500. In accordance with various embodiments, the data store 508 can comprise volatile memory and/or nonvolatile memory, such as described herein.

In accordance with various embodiments, a system (e.g., the system 100, the system 300, the system 400, or other system) as disclosed herein, electronic components of such system, and/or one or more other electronic components or other systems associated with such system, and/or electronic circuitry relating thereto, can be formed in or on one or more integrated circuits (IC), one or more IC chips, and/or one or more dies. For example, such a system as disclosed herein can be formed on a single die, or portions of such system can be formed on a desired number of dies that can be associated with (e.g., electrically connected) to each other. In some embodiments, such a system as disclosed herein, or a desired portion thereof, can be, can comprise, and/or can be formed as or part of an application-specific IC (ASIC).

The aforementioned devices and/or systems have been described with respect to interaction between several components. It should be appreciated that such systems and components can include those components or sub-components specified therein, some of the specified components or sub-components, and/or additional components. Sub-components could also be implemented as components coupled to and/or communicatively coupled to other components rather than included within parent components. Further yet, one or more components and/or sub-components may be combined into a single component providing aggregate functionality. The components may also interact with one or more other components not specifically described herein for the sake of brevity, but known by those of skill in the art.

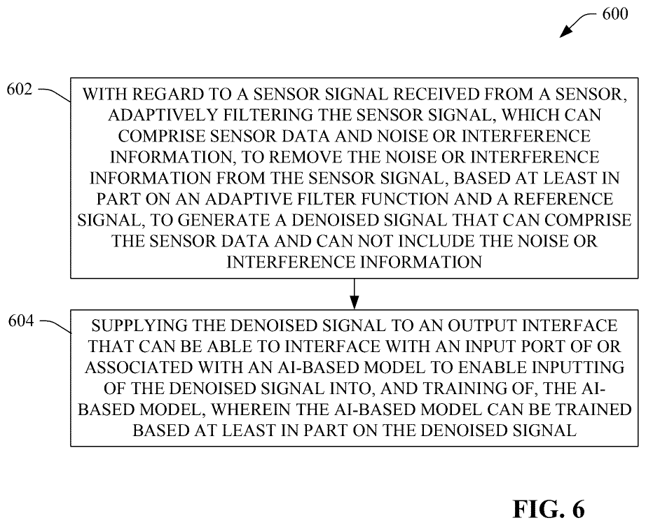

In view of the example systems and/or devices described herein, example methods that can be implemented in accordance with the disclosed subject matter can be further appreciated with reference to flowcharts in FIGS. 6-8. FIGS. 6-8 illustrates methods and/or flow diagrams in accordance with the disclosed subject matter. For simplicity of explanation, the methods are depicted and described as a series of acts. It is to be understood and appreciated that the subject disclosure is not limited by the acts illustrated and/or by the order of acts, for example acts can occur in various orders and/or concurrently, and with other acts not presented and described herein. Furthermore, not all illustrated acts may be required to implement the methods in accordance with the disclosed subject matter.

Referring to FIG. 6, illustrated is a flow diagram of an example method 600 that that can desirably and adaptively cancel noise in a sensor signal received from a sensor component to generate a denoised sensor signal that can be provided to an AI-based model to facilitate training (e.g., adaptive training) of the AI-based model, in accordance with various aspects and embodiments of the disclosed subject matter. The method 600 can be implemented, for example, by or utilizing a system or device comprising the adaptive noise canceler component, and/or a processor and associated memory (e.g., data store).

At 602, with regard to a sensor signal received from a sensor, the sensor signal, which can comprise sensor data and noise or interference information, can be adaptively filtered to remove the noise or interference information from the sensor signal, based at least in part on an adaptive filter function and a reference signal, to generate a denoised signal that can comprise the sensor data and cannot include the noise or interference information. In some embodiments, the adaptive noise canceler component (e.g., an input port of the adaptive noise canceler component) can receive the sensor signal from the sensor, wherein the sensor signal can comprise the sensor data and the noise or interference information. In accordance with various embodiments, the adaptive noise canceler component adaptively filter the sensor signal to remove the noise or interference information from the sensor signal, based at least in part on the adaptive filter function and the reference signal, to generate the denoised signal (e.g., denoised sensor signal) that can comprise the sensor data and cannot include the noise or interference information or at least does not include a substantial portion of the noise or interference information. In accordance with various embodiments, the reference signal can be an internal reference signal that can be set to a defined value (e.g., a defined value of 1), or can be an external reference signal that can be received from a reference sensor component and can have a variable value that can be based at least in part on a condition(s) sensed by the reference sensor component, such as described herein.

At 604, the denoised signal can be supplied to an output interface that can be able to interface with an input port of or associated with an AI-based model to enable inputting of the denoised signal into, and training of, the AI-based model, wherein the AI-based model can be trained based at least in part on the denoised signal. In some embodiments, the adaptive noise canceler component can provide (e.g., supply, communicate, or present) the denoised signal to the output interface (e.g., of the adaptive noise canceler component) that can be able to interface with the input port of or associated with the AI-based model to enable inputting of the denoised signal into, and training of, the AI-based model. In some embodiments, the AI-based model can be trained (e.g., by the trainer component of the AI component) based at least in part on the denoised signal, such as described herein.

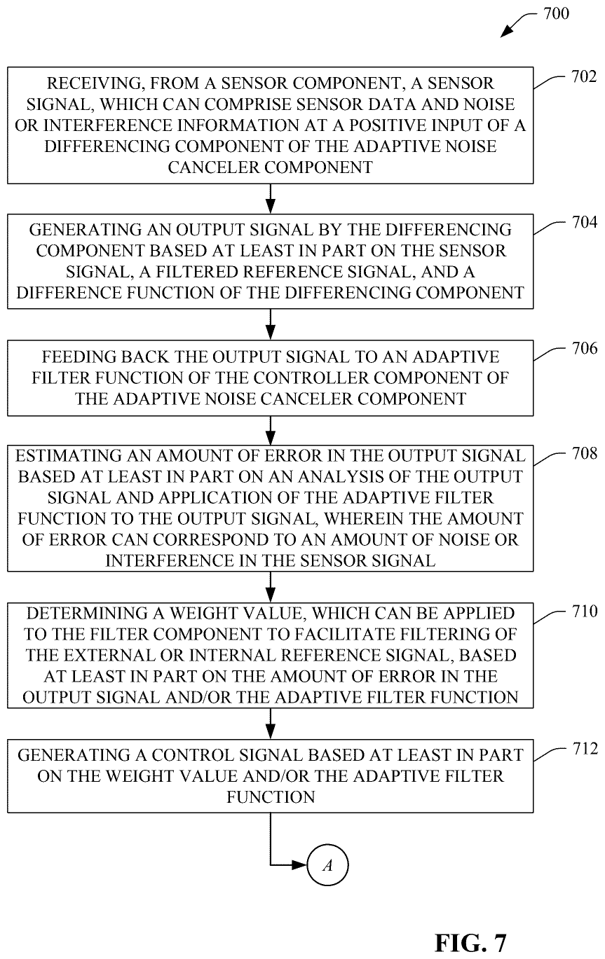

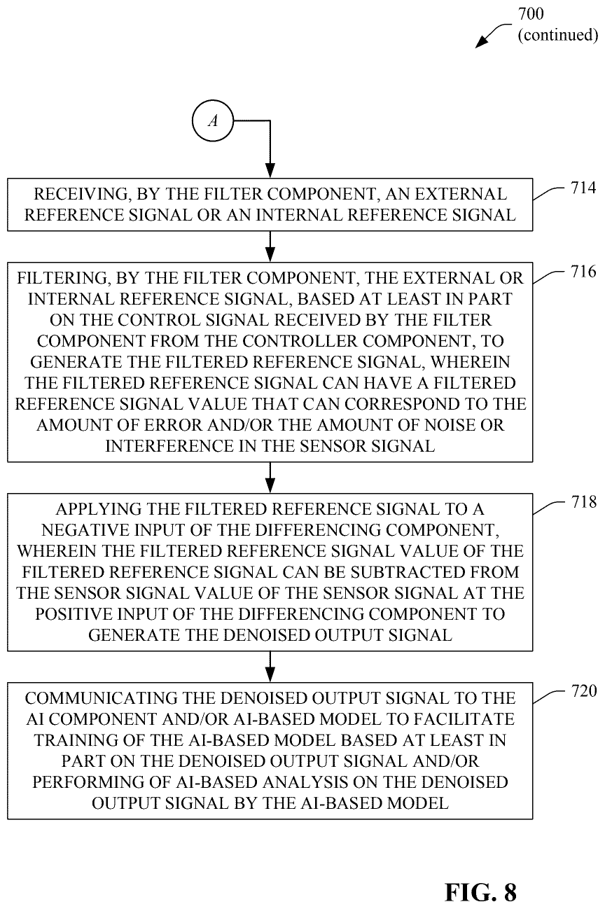

Turning to FIGS. 7 and 8, FIGS. 7 and 8 illustrate a flow diagram of another example method 700 that that can desirably and adaptively cancel noise in a sensor signal received from a sensor component to generate a denoised sensor signal that can be provided to an AI-based model to facilitate training (e.g., adaptive training) of the AI-based model, in accordance with various aspects and embodiments of the disclosed subject matter. The method 700 can be implemented, for example, by or utilizing a system or device comprising the adaptive noise canceler component, and/or a processor and associated memory (e.g., data store).

At 702, a sensor signal, which can comprise sensor data and noise or interference information, can be received, from a sensor component, at a positive input of a differencing component of the adaptive noise canceler component. In some embodiments, the adaptive noise canceler component can receive the sensor signal from the sensor component, which can comprise one or more sensors of one or more various sensor types, such as described herein. In certain embodiments, the sensor signal can be input (e.g., applied) to the positive input of the differencing component.

At 704, an output signal can be generated by the differencing component based at least in part on the sensor signal, a filtered reference signal, and a difference function of the differencing component. In some embodiments, the differencing component can generate the output signal based at least in part on the sensor signal, the filtered reference signal, and the difference function of the differencing component, such as described herein. The filtered reference signal can be generated by the filter component of the adaptive noise canceler component, such as described herein.

At 706, the output signal can be fed back to an adaptive filter function of the controller component of the adaptive noise canceler component. For instance, the output signal, in addition to being provided as an output from the adaptive noise canceler component, also can be fed back to the adaptive filter function.

At 708, an amount of error in the output signal can be estimated based at least in part on an analysis of the output signal and application of the adaptive filter function to the output signal, wherein the amount of error can correspond to an amount of noise or interference in the sensor signal. In some embodiments, the controller component can estimate or determine the amount of error in the output signal based at least in part on the results of the analysis of the output signal and application of the adaptive filter function to the output signal.

At 710, a weight value, which can be applied to the filter component to facilitate filtering of the external or internal reference signal, can be determined based at least in part on the amount of error in the output signal and/or the adaptive filter function. In some embodiments, the controller component can determine the weight value that can be applied to the filter component to facilitate filtering of the external or internal reference signal based at least in part on the amount of error in the output signal and/or the adaptive filter function, such as described herein.

At 712, a control signal can be generated based at least in part on the weight value and/or the adaptive filter function. In some embodiments, the controller component can determine and generate the control signal based at least in part on the weight value and/or the adaptive filter function, wherein the control signal can have a control signal value that correspond to the weight value, the amount of error in the output signal, and/or the amount of noise or interference in the output signal, such as described herein. At this point, the method 700 can proceed to reference point A, wherein the method 700 can proceed from reference point A as described herein and as shown in FIG. 8.

At 714, an external reference signal or an internal reference signal can be received by the filter component. In accordance with various embodiments, the filter component of the adaptive noise canceler component can receive the external reference signal from the reference sensor component or the internal reference signal generated by the adaptive noise canceler component. In some embodiments, if it is the external reference signal that is received, the external reference signal can have an external reference signal value that can vary based at least in part on the condition(s) sensed or measured by the reference sensor component, such as described herein. In certain embodiments, if it is the internal reference signal that is received, the internal reference signal can have a desired constant reference signal value (e.g., 1), such as described herein.

At 716, the external or internal reference signal can be filtered by the filter component, based at least in part on the control signal received by the filter component from the controller component, to generate the filtered reference signal, wherein the filtered reference signal can have a filtered reference signal value that can correspond to the amount of error and/or the amount of noise or interference in the sensor signal. In some embodiments, the controller component can communicate or apply the control signal to the filter component, and the filter component can filter the external or internal reference signal, based at least in part on the control signal, to generate the filtered reference signal.

At 718, the filtered reference signal can be applied to a negative input of the differencing component, wherein the filtered reference signal value of the filtered reference signal can be subtracted from the sensor signal value of the sensor signal at the positive input of the differencing component to generate the denoised output signal. In certain embodiments, the filter component can provide (e.g., communicate or apply) the filtered reference signal as an output to the negative input of the differencing component, and the differencing component can subtract the filtered reference signal value from the sensor signal value to generate the denoised output signal. The denoised output signal (e.g., denoised sensor signal) can comprise the sensor value generated by the sensor component, wherein the noise or interference that was in the sensor signal can be mitigated, eliminated, reduced, and/or minimized such that there can be no noise or interference, or at least virtually no noise or interference, in the denoised output signal.

At 720, the denoised output signal (e.g., denoised sensor signal) can be communicated to the AI component and/or AI-based model to facilitate training of the AI-based model based at least in part on the denoised output signal and/or performing of AI-based analysis on the denoised output signal by the AI-based model. In some embodiments, the adaptive noise canceler component can communicate the denoised output signal to the AI component and/or AI-based model via the interface component of the adaptive noise canceler component, wherein the interface component can be interfaced with the input (e.g., input port) of the AI component and/or AI-based model, such as described herein.

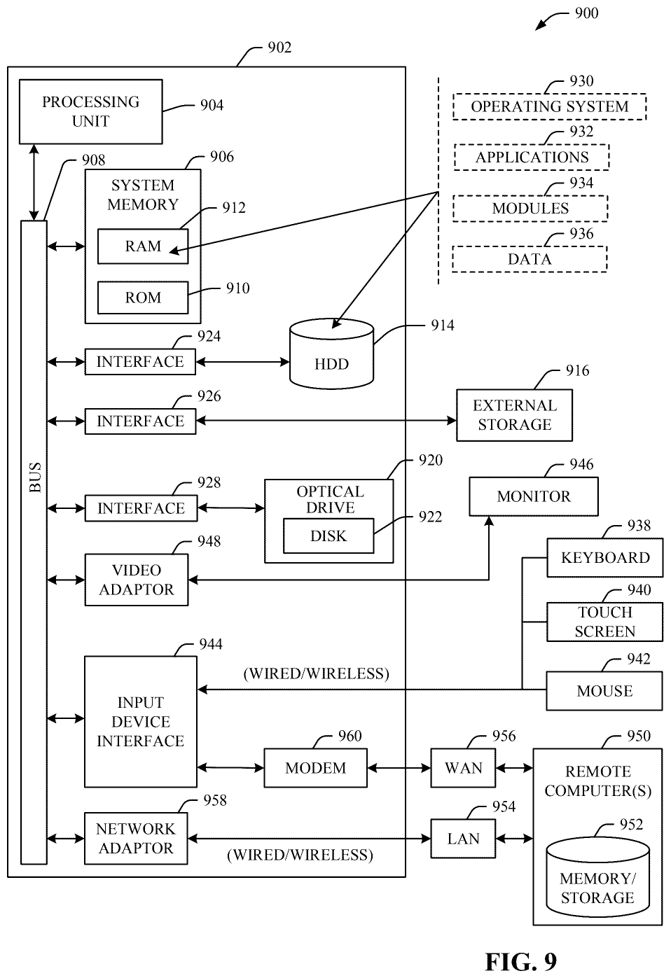

In order to provide additional context for various embodiments described herein, FIG. 9 and the following discussion are intended to provide a brief, general description of a suitable computing environment 900 in which the various embodiments of the embodiments described herein can be implemented. While the embodiments have been described above in the general context of computer-executable instructions that can run on one or more computers, those skilled in the art will recognize that the embodiments can also be implemented in combination with other program modules and/or as a combination of hardware and software.

Generally, program modules include routines, programs, components, data structures, etc., that perform particular tasks or implement particular abstract data types. Moreover, those skilled in the art will appreciate that the methods can be practiced with other computer system configurations, including single-processor or multiprocessor computer systems, minicomputers, mainframe computers, IoT devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and include any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 9, the example environment 900 for implementing various embodiments of the aspects described herein includes a computer 902, the computer 902 including a processing unit 904, a system memory 906 and a system bus 908. The system bus 908 couples system components including, but not limited to, the system memory 906 to the processing unit 904. The processing unit 904 can be any of various commercially available processors. Dual microprocessors and other multi-processor architectures can also be employed as the processing unit 904.

The system bus 908 can be any of several types of bus structure that can further interconnect to a memory bus (with or without a memory controller), a peripheral bus, and a local bus using any of a variety of commercially available bus architectures. The system memory 906 includes ROM 910 and RAM 912. A basic input/output system (BIOS) can be stored in a non-volatile memory such as ROM, erasable programmable read only memory (EPROM), EEPROM, which BIOS contains the basic routines that help to transfer information between elements within the computer 902, such as during startup. The RAM 912 can also include a high-speed RAM such as static RAM for caching data.

The computer 902 further includes an internal hard disk drive (HDD) 914 (e.g., EIDE, SATA), one or more external storage devices 916 (e.g., a magnetic floppy disk drive (FDD) 916, a memory stick or flash drive reader, a memory card reader, etc.) and an optical disk drive 920 (e.g., which can read or write from a CD-ROM disc, a DVD, a BD, etc.). While the internal HDD 914 is illustrated as located within the computer 902, the internal HDD 914 also can be configured for external use in a suitable chassis (not shown).

Additionally, while not shown in environment 900, a solid state drive (SSD) could be used in addition to, or in place of, an HDD 914. The HDD 914, external storage device(s) 916 and optical disk drive 920 can be connected to the system bus 908 by an HDD interface 924, an external storage interface 926 and an optical drive interface 928, respectively. The interface 924 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 902, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 912, including an operating system 930, one or more application programs 932, other program modules 934 and program data 936. All or portions of the operating system, applications, modules, and/or data can also be cached in the RAM 912. The systems and methods described herein can be implemented utilizing various commercially available operating systems or combinations of operating systems.

Computer 902 can optionally comprise emulation technologies. For example, a hypervisor (not shown) or other intermediary can emulate a hardware environment for operating system 930, and the emulated hardware can optionally be different from the hardware illustrated in FIG. 9. In such an embodiment, operating system 930 can comprise one virtual machine (VM) of multiple VMs hosted at computer 902. Furthermore, operating system 930 can provide runtime environments, such as the Java runtime environment or the .NET framework, for applications 932. Runtime environments are consistent execution environments that allow applications 932 to run on any operating system that includes the runtime environment. Similarly, operating system 930 can support containers, and applications 932 can be in the form of containers, which are lightweight, standalone, executable packages of software that include, e.g., code, runtime, system tools, system libraries and settings for an application.

Further, computer 902 can be enabled with a security module, such as a trusted processing module (TPM). For instance, with a TPM, boot components hash next in time boot components, and wait for a match of results to secured values, before loading a next boot component. This process can take place at any layer in the code execution stack of computer 902, e.g., applied at the application execution level or at the operating system (OS) kernel level, thereby enabling security at any level of code execution.

A user can enter commands and information into the computer 902 through one or more wired/wireless input devices, e.g., a keyboard 938, a touch screen 940, and a pointing device, such as a mouse 942. Other input devices (not shown) can include a microphone, an infrared (IR) remote control, a radio frequency (RF) remote control, or other remote control, a joystick, a virtual reality controller and/or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 904 through an input device interface 944 that can be coupled to the system bus 908, but can be connected by other interfaces, such as a parallel port, an IEEE 1394 serial port, a game port, a USB port, an IR interface, a BLUETOOTH® interface, or other interface.

A monitor 946 or other type of display device can also be connected to the system bus 908 via an interface, such as a video adapter 948. In addition to the monitor 946, a computer typically includes other peripheral output devices (not shown), such as speakers, printers, or other peripheral output device.

The computer 902 can operate in a networked environment using logical connections via wired and/or wireless communications to one or more remote computers, such as a remote computer(s) 950. The remote computer(s) 950 can be a workstation, a server computer, a router, a personal computer, portable computer, microprocessor-based entertainment appliance, a peer device or other common network node, and typically includes many or all of the elements described relative to the computer 902, although, for purposes of brevity, only a memory/storage device 952 is illustrated. The logical connections depicted include wired/wireless connectivity to a local area network (LAN) 954 and/or larger networks, e.g., a wide area network (WAN) 956. Such LAN and WAN networking environments are commonplace in offices and companies, and facilitate enterprise-wide computer networks, such as intranets, all of which can connect to a global communications network, e.g., the Internet.

When used in a LAN networking environment, the computer 902 can be connected to the local network 954 through a wired and/or wireless communication network interface or adapter 958. The adapter 958 can facilitate wired or wireless communication to the LAN 954, which can also include a wireless access point (AP) disposed thereon for communicating with the adapter 958 in a wireless mode.

When used in a WAN networking environment, the computer 902 can include a modem 960 or can be connected to a communications server on the WAN 956 via other means for establishing communications over the WAN 956, such as by way of the Internet. The modem 960, which can be internal or external and a wired or wireless device, can be connected to the system bus 908 via the input device interface 944. In a networked environment, program modules depicted relative to the computer 902 or portions thereof, can be stored in the remote memory/storage device 952. It will be appreciated that the network connections shown are examples and other means of establishing a communications link between the computers can be used.

When used in either a LAN or WAN networking environment, the computer 902 can access cloud storage systems or other network-based storage systems in addition to, or in place of, external storage devices 916 as described above. Generally, a connection between the computer 902 and a cloud storage system can be established over a LAN 954 or WAN 956, e.g., by the adapter 958 or modem 960, respectively. Upon connecting the computer 902 to an associated cloud storage system, the external storage interface 926 can, with the aid of the adapter 958 and/or modem 960, manage storage provided by the cloud storage system as it would other types of external storage. For instance, the external storage interface 926 can be configured to provide access to cloud storage sources as if those sources were physically connected to the computer 902.

The computer 902 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

Wi-Fi, or Wireless Fidelity, allows connection to the Internet from a couch at home, in a hotel room, or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, etc.) to provide secure, reliable, fast wireless connectivity. A Wi-Fi network can be used to connect computers to each other, to the Internet, and to wired networks (which use IEEE 802.3 or Ethernet). Wi-Fi networks operate in the unlicensed 2.4 and 5 GHz radio bands, at an 11 Mbps (802.11a) or 54 Mbps (802.11b) data rate, for example, or with products that contain both bands (dual band), so the networks can provide real-world performance similar to the basic 10BaseT wired Ethernet networks used in many offices.

Various aspects or features described herein can be implemented as a method, apparatus, system, or article of manufacture using standard programming or engineering techniques. In addition, various aspects or features disclosed in the subject specification can also be realized through program modules that implement at least one or more of the methods disclosed herein, the program modules being stored in a memory and executed by at least a processor. Other combinations of hardware and software or hardware and firmware can enable or implement aspects described herein, including disclosed method(s). The term “article of manufacture” as used herein is intended to encompass a computer program accessible from any computer-readable device, carrier, or storage media. For example, computer-readable storage media can include but are not limited to magnetic storage devices (e.g., hard disk, floppy disk, magnetic strips, etc.), optical discs (e.g., compact disc (CD), digital versatile disc (DVD), blu-ray disc (BD), etc.), smart cards, and memory devices comprising volatile memory and/or non-volatile memory (e.g., flash memory devices, such as, for example, card, stick, key drive, etc.), or the like. In accordance with various implementations, computer-readable storage media can be non-transitory computer-readable storage media and/or a computer-readable storage device can comprise computer-readable storage media.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. A processor can be or can comprise, for example, multiple processors that can include distributed processors or parallel processors in a single machine or multiple machines. Additionally, a processor can comprise or refer to an integrated circuit, an application specific integrated circuit (ASIC), a digital signal processor (DSP), a programmable gate array (PGA), a field programmable gate array (FPGA), a programmable logic controller (PLC), a complex programmable logic device (CPLD), a state machine, a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor may also be implemented as a combination of computing processing units.

A processor can facilitate performing various types of operations, for example, by executing computer-executable instructions. When a processor executes instructions to perform operations, this can include the processor performing (e.g., directly performing) the operations and/or the processor indirectly performing operations, for example, by facilitating (e.g., facilitating operation of), directing, controlling, or cooperating with one or more other devices or components to perform the operations. In some implementations, a memory can store computer-executable instructions, and a processor can be communicatively coupled to the memory, wherein the processor can access or retrieve computer-executable instructions from the memory and can facilitate execution of the computer-executable instructions to perform operations.

In certain implementations, a processor can be or can comprise one or more processors that can be utilized in supporting a virtualized computing environment or virtualized processing environment. The virtualized computing environment may support one or more virtual machines representing computers, servers, or other computing devices. In such virtualized virtual machines, components such as processors and storage devices may be virtualized or logically represented.

In the subject specification, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory, or can include both volatile and nonvolatile memory.

By way of illustration, and not limitation, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

As used in this application, the terms “component,” “system,” “platform,” “framework,” “layer,” “interface,” “agent,” and the like, can refer to and/or can include a computer-related entity or an entity related to an operational machine with one or more specific functionalities. The entities disclosed herein can be either hardware, a combination of hardware and software, software, or software in execution. For example, a component may be, but is not limited to being, a process running on a processor, a processor, an object, an executable, a thread of execution, computer-executable instructions, a program, and/or a computer. By way of illustration, both an application running on a server and the server can be a component. One or more components may reside within a process and/or thread of execution and a component may be localized on one computer and/or distributed between two or more computers.

In another example, respective components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

It is to be appreciated and understood that components (e.g., adaptive noise canceler component, sensor component, AI component, model, differencing component, filter component, controller component, adaptive filter function, processor component, data store, or other component), as described with regard to a particular device, system, or method, can comprise the same or similar functionality as respective components (e.g., respectively named components or similarly named components) as described with regard to other devices, systems, or methods disclosed herein.

Although the description has been provided with respect to particular embodiments thereof, these particular embodiments are merely illustrative and not restrictive.

While particular embodiments have been described herein, latitudes of modification, various changes, and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form.

As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

What has been described above includes examples of aspects of the disclosed subject matter. It is, of course, not possible to describe every conceivable combination of components or methods for purposes of describing the disclosed subject matter, but one of ordinary skill in the art may recognize that many further combinations and permutations of the disclosed subject matter are possible. Accordingly, the disclosed subject matter is intended to embrace all such alterations, modifications and variations that fall within the spirit and scope of the appended claims. Furthermore, to the extent that the terms “includes,” “has,” or “having,” or variations thereof, are used in either the detailed description or the claims, such terms are intended to be inclusive in a manner similar to the term “comprising” as “comprising” is interpreted when employed as a transitional word in a claim.

What is claimed is:

1. A system, comprising:
at least one memory that stores machine-executable components; and
at least one processor that executes the machine-executable components stored in the at least one memory, wherein the machine-executable components comprise:
an adaptive noise canceler component configured to adaptively filter a sensor signal, comprising sensor data, that is received from a sensor component to cancel noise from the sensor signal, based at least in part on an adaptive filter function and an internal reference signal, to generate a denoised signal that comprises the sensor data; and
an interface component configured to interface with an artificial intelligence-based model and initiate training of the artificial intelligence-based model by communication or application of the denoised signal to an input port of the artificial intelligence-based model, wherein the artificial intelligence-based model is trained based at least in part on the denoised signal.

2. The system of claim 1, wherein the adaptive filter function comprises or employs at least one adaptive filter or noise cancellation function or algorithm, to facilitate canceling the noise from the sensor signal.

3. The system of claim 1, wherein the noise relates to a bias, a drift, an environmental, or an interference behavior or condition associated with the sensor component or the sensor signal.

4. The system of claim 1, wherein the adaptive noise canceler component further comprises:
a differencing component configured to receive the sensor signal at a positive input port of the differencing component and a filtered reference signal at a negative input port of the differencing component, and generate an output signal as an output from an output port of the differencing component, wherein the output signal is based on the sensor signal, the filtered reference signal, and a difference function of the differencing component;
a controller component configured to receive the output signal fed back from the output port of the differencing component, and generate a control signal based on the output signal and the adaptive filter function; and
a filter component that is configured to filter the internal reference signal, based on the internal reference signal and the control signal, to generate the filtered reference signal, wherein the internal reference signal has a constant value of one, and wherein the denoised signal is based on the output signal.

5. The system of claim 4, wherein the controller component is configured to determine or estimate a first amount of error in the output signal and determine a weight value to apply to the filter component to facilitate filtering of the internal reference signal based on an analysis of the output signal and an application of the adaptive filter function, wherein the weight value corresponds to the first amount of error, wherein the control signal comprises or is determined based on the weight value, wherein the first amount of error corresponds to a second amount of the noise, and wherein the filtered reference signal corresponds to the first amount of error or the second amount of the noise.

6. The system of claim 1, further comprising the sensor component configured to be interfaced with the adaptive noise canceler component, sense a condition associated with the sensor component, and generate the sensor data based on the condition, wherein the adaptive noise canceler component receives the sensor signal from the sensor component.

7. The system of claim 6, wherein the sensor component comprises at least one of a micro-electromechanical systems (MEMS) sensor, an accelerometer, a gyroscope, an environmental condition sensor, an optical sensor, an image sensor, a chemical sensor, a sound sensor, a pressure sensor, a temperature sensor, a humidity sensor, a quartz sensor, a magnetometer, a health sensor, a photoplethysmography sensor, an electrocardiography sensor, or a gas sensor.

8. The system of claim 1, further comprising:
an artificial intelligence component configured to comprise a trainer component, and comprise or be associated with the artificial intelligence-based model, wherein the trainer component is configured to manage input or the application of the denoised signal to the input port of the artificial intelligence-based model, and training of the artificial intelligence-based model based on the denoised signal.

9. A device, comprising:
an adaptive noise canceler component configured to adaptively filter a sensor signal, comprising sensor information, that is received from a sensor component to filter out noise from the sensor signal, based at least in part on an adaptive filter function and a reference signal, to generate a noise-canceled signal that comprises the sensor information and does not include the noise filtered out from the sensor signal; and
an interface component configured to interface with an artificial intelligence-based model and facilitate training of the artificial intelligence-based model by communication or application of the noise-canceled signal to an input port of the artificial intelligence-based model, wherein the artificial intelligence-based model is trained based at least in part on the noise-canceled signal.

10. The device of claim 9, wherein the adaptive filter function comprises or employs a least mean squares (LMS)-based adaptive filter function or algorithm, a recursive least squares (RLS)-based adaptive filter function or algorithm, a normalized least mean squares (NLMS)-based adaptive filter function or algorithm, a variable least mean squares (VLMS)-based adaptive filter function or algorithm, an affine projection-based adaptive filter function or algorithm, or a Kalman-based adaptive filter function or algorithm, to facilitate filtering out the noise from the sensor signal.

11. The device of claim 9, wherein the noise relates to a bias, a drift, an environmental, or an interference behavior or condition associated with the sensor component or the sensor signal.

12. The device of claim 9, wherein the reference signal is an internal reference signal that is internal to the device, and is set to a constant value of one, and wherein the adaptive noise canceler component further comprises:
a differencing component configured to receive the sensor signal at a positive input port of the differencing component and a noise cancellation signal at a negative input port of the differencing component, and generate an output signal as an output from an output port of the differencing component;
a controller component configured to receive the output signal fed back from the output port of the differencing component, and generate a control signal based on the output signal and the adaptive filter function; and
a filter component that is configured to filter the internal reference signal, based on the internal reference signal and the control signal, to generate the noise cancellation signal, wherein the noise-canceled signal is based on the output signal.

13. The device of claim 12, wherein the controller component is configured to determine or estimate a first amount of error in the output signal and determine a weight value to apply to the filter component to facilitate filtering of the internal reference signal based on a result of an analysis of the output signal and an application of the adaptive filter function, wherein the weight value corresponds to the first amount of error, wherein the control signal comprises or is determined based on the weight value, wherein the first amount of error corresponds to a second amount of the noise, and wherein the noise cancellation signal corresponds to the first amount of error or the second amount of the noise.

14. The device of claim 9, further comprising the sensor component configured to be interfaced with the adaptive noise canceler component, sense a condition associated with the sensor component, and generate the sensor information based on the condition, wherein the adaptive noise canceler component receives the sensor signal from the sensor component.

15. The device of claim 9, wherein the sensor component is a first sensor component, wherein the sensor signal is a first sensor signal, wherein the adaptive noise canceler component is configured to receive a second sensor signal from a second sensor component, wherein the second sensor signal relates to an environmental or interference condition associated with the first sensor component or the first sensor signal, and wherein the reference signal is the second sensor signal or is generated based at least in part on the second sensor signal.

16. The device of claim 9, wherein the sensor component comprises at least one of a micro-electromechanical systems (MEMS) sensor, an accelerometer, a gyroscope, an environmental condition sensor, an optical sensor, an image sensor, a chemical sensor, a sound sensor, a pressure sensor, a temperature sensor, a humidity sensor, a quartz sensor, a magnetometer, a health sensor, a photoplethysmography sensor, an electrocardiography sensor, or a gas sensor.

17. A method, comprising:
with regard to a sensor signal received from a sensor, adaptively filtering the sensor signal, comprising sensor data and noise or interference information, to remove the noise or interference information from the sensor signal, based at least in part on an adaptive filter function and a reference signal, to generate a denoised signal that comprises the sensor data and does not include the noise or interference information; and
supplying the denoised signal to an output interface that is able to interface with an input port of or associated with an artificial intelligence-based model to enable inputting of the denoised signal into, and training of, the artificial intelligence-based model, wherein the artificial intelligence-based model is trained based at least in part on the denoised signal.

18. The method of claim 17, wherein the adaptive filter function comprises or employs at least one adaptive filter or noise cancellation function or algorithm to facilitate removing the noise or interference information from the sensor signal.

19. The method of claim 17, wherein the sensor is a first sensor, wherein the sensor signal is a first sensor signal, wherein the noise relates to a bias, a drift, an environmental, or an interference behavior or condition associated with the first sensor or the first sensor signal,
wherein the reference signal is an internal reference signal that is internal to an adaptive noise canceler that adaptively filters the first sensor signal, and is set to a constant value of one, or the reference signal is an external reference signal external to and received by the adaptive noise canceler, and
wherein the external reference signal is, or is generated based at least in part on, a second sensor signal received from a second sensor that senses the condition associated with the first sensor or the first sensor signal.

20. The method of claim 17, wherein the sensor comprises at least one of a micro-electromechanical systems (MEMS) sensor, an accelerometer, a gyroscope, an environmental condition sensor, an optical sensor, an image sensor, a chemical sensor, a sound sensor, a pressure sensor, a temperature sensor, a humidity sensor, a quartz sensor, a magnetometer, a health sensor, a photoplethysmography sensor, an electrocardiography sensor, or a gas sensor.
